(19) United States
(12) Patent Application Publication
(10) Pub. No.: US 2025/0160030 A1
(43) Pub. Date: May 15, 2025

(54) IMAGE SENSOR

(71) Applicant: SAMSUNG ELECTRONICS CO., LTD., Suwon-si (KR)

(72) Inventors: Ingyu Baek, Suwon-si (KR); Soonhyung Hong, Suwon-si (KR)

(73) Assignee: SAMSUNG ELECTRONICS CO., LTD., Suwon-si (KR)

(21) Appl. No.: 18/882,272

(22) Filed: Sep. 11, 2024

(30) Foreign Application Priority Data
Nov. 15, 2023 (KR) 10-2023-0158619

(51) Int. Cl. H01L 27/146; H04N 25/531; H04N 25/772; H04N 25/78

(52) U.S. Cl. CPC H10F 39/811; H04N 25/531; H04N 25/772; H04N 25/78; H10F 39/18; H10F 39/8037

(57) ABSTRACT

An image sensor includes: a top layer including a photodiode included in a pixel and a transfer transistor configured to transfer an electrical signal generated by the photodiode; a first middle layer under the top layer and bonded to the top layer, wherein the first middle layer includes a plurality of capacitors connected to the transfer transistor through a first output node connected to the transfer transistor, and a plurality of sampling transistors connected to the plurality of capacitors and configured to control the plurality of capacitors; a second middle layer under the first middle layer and bonded to the first middle layer, wherein the second middle layer includes a source-follow transistor connected to the plurality of sampling transistors through a second output node; and a bottom layer under the second middle layer and bonded to the second middle layer, wherein the bottom layer includes an analog-to-digital converter (ADC) circuit configured to process a pixel signal output through the source-follow transistor.

### CROSS-REFERENCE TO RELATED APPLICATION

This application is based on and claims priority to Korean Patent Application No. 10-2023-0158619, filed on Nov. 15, 2023, in the Korean Intellectual Property Office, the disclosure of which is incorporated by reference herein in its entirety.

### BACKGROUND

The disclosure relates to an image sensor, and more particularly, to an image sensor which may provide a reduction in pixel size and decreased noise.

Image sensors, which may capture an image and convert the image into an electrical signal, may be used in cameras equipped in vehicles, security devices, and robots as well as general electronic devices for consumers such as digital cameras, mobile phone cameras, and portable camcorders. In image sensors, pixels may be progressively reduced in size, and it may be beneficial to decrease noise caused by the reduction in pixel size.

### SUMMARY

Provided is an image sensor which may allow a reduction in pixel size and decreased noise.

In accordance with an aspect of the disclosure, an image sensor includes: a top layer including a photodiode included in a pixel and a transfer transistor configured to transfer an electrical signal generated by the photodiode; a first middle layer under the top layer and bonded to the top layer, wherein the first middle layer includes a plurality of capacitors connected to the transfer transistor through a first output node connected to the transfer transistor, and a plurality of sampling transistors connected to the plurality of capacitors and configured to control the plurality of capacitors; a second middle layer under the first middle layer and bonded to the first middle layer, wherein the second middle layer includes a source-follow transistor connected to the plurality of sampling transistors through a second output node; and a bottom layer under the second middle layer and bonded to the second middle layer, wherein the bottom layer includes an analog-to-digital converter (ADC) circuit configured to process a pixel signal output through the source-follow transistor.

In accordance with an aspect of the disclosure, an image sensor includes: a top layer including a photodiode included in a pixel and a transfer transistor configured to transfer an electrical signal generated by the photodiode; a first middle layer under the top layer and bonded to the top layer, wherein the first middle layer includes a source-follow transistor connected to the transfer transistor through a floating diffusion node; a second middle layer under the first middle layer and bonded to the first middle layer, wherein the second middle layer includes a plurality of capacitors connected to the transfer transistor through the floating diffusion node and a plurality of switching transistors connected to the plurality of capacitors and configured to control the plurality of capacitors; and a bottom layer under the second middle layer and bonded to the second middle layer, wherein the bottom layer includes an analog-to-digital converter (ADC) circuit configured to process a pixel signal output through the source-follow transistor.

In accordance with an aspect of the disclosure, an image sensor includes: a top layer including a photodiode included in a pixel and a transfer transistor configured to transfer an electrical signal generated by the photodiode; a first middle layer under the top layer and bonded to the top layer, wherein the first middle layer includes an analog-to-digital converter (ADC) circuit connected to the transfer transistor to process the electrical signal; a second middle layer under the first middle layer and bonded to the first middle layer, wherein the second middle layer includes a plurality of capacitors connected to the transfer transistor through a floating diffusion node and a plurality of switching transistors connected to the plurality of capacitors and configured to control the plurality of capacitors; and a bottom layer under the second middle layer and bonded to the second middle layer, wherein the bottom layer includes a plurality of additional transistors configured to drive the pixel.

In accordance with an aspect of the disclosure, an image sensor includes: a top layer including a photodiode included in a pixel and a transfer transistor configured to transfer an electrical signal generated by the photodiode; a first middle layer under the top layer and bonded to the top layer, wherein the first middle layer includes a source-follow transistor connected to the transfer transistor through a first output node; a second middle layer under the first middle layer and bonded to the first middle layer, wherein the second middle layer includes a plurality of capacitors connected to the source-follow transistor, and a plurality of sampling transistors connected to the plurality of capacitors and configured to control the plurality of capacitors; and a bottom layer under the second middle layer and bonded to the second middle layer, wherein the bottom layer includes an analog-to-digital converter (ADC) circuit configured to process a pixel signal output through the source-follow transistor.

In accordance with an aspect of the disclosure, an image sensor includes: a top layer including a photodiode included in a pixel and a transfer transistor configured to transfer an electrical signal generated by the photodiode; a first middle layer under the top layer and bonded to the top layer, wherein the first middle layer includes a plurality of capacitors connected to the transfer transistor through a floating diffusion node and a plurality of switching transistors connected to the plurality of capacitors and configured to control the plurality of capacitors; a second middle layer under the first middle layer and bonded to the first middle layer, wherein the second middle layer includes an analog-to-digital converter (ADC) circuit connected to the transfer transistor and configured to process the electrical signal; and a bottom layer under the second middle layer and bonded to the second middle layer, wherein the bottom layer includes a plurality of additional transistors configured to drive the pixel.

### BRIEF DESCRIPTION OF DRAWINGS

Embodiments will be more clearly understood from the following detailed description taken in conjunction with the accompanying drawings in which:

FIG. 1 is a block diagram illustrating an image sensor according to an embodiment;

FIGS. 2A and 2B are diagrams for describing an operation of an image sensor according to an embodiment;

FIG. 3 is a schematic cross-sectional view of a structure of an image sensor according to an embodiment;

FIG. 4 is a circuit diagram of an image sensor according to an embodiment;

FIG. 5 is a circuit diagram of an image sensor according to an embodiment;

FIG. 6 is a circuit diagram of an image sensor according to an embodiment;

FIG. 7 is a schematic cross-sectional view of a structure of an image sensor according to an embodiment;

FIG. 8 is a schematic cross-sectional view of a structure of an image sensor according to an embodiment;

FIG. 9 is a schematic cross-sectional view of a structure of an image sensor according to an embodiment;

FIG. 10 is a schematic cross-sectional view of a structure of an image sensor according to an embodiment;

FIG. 11 is a schematic cross-sectional view of a structure of an image sensor according to an embodiment;

FIG. 12 is a schematic cross-sectional view of a structure of an image sensor according to an embodiment;

FIG. 13 is a schematic cross-sectional view of a structure of an image sensor according to an embodiment;

FIGS. 14 to 16 are cross-sectional views of a method of manufacturing the image sensor of FIG. 3, according to an embodiment;

FIGS. 17 and 18 are cross-sectional views of a method of manufacturing the image sensor of FIG. 3, according to an embodiment;

FIGS. 19 to 21 are cross-sectional views of a method of manufacturing the image sensor of FIG. 3, according to an embodiment;

FIGS. 22 and 23 are cross-sectional views of a method of manufacturing the image sensor of FIG. 3, according to an embodiment; and

FIGS. 24 and 25 are cross-sectional views of a method of manufacturing the image sensor of FIG. 3, according to an embodiment.

### DETAILED DESCRIPTION OF EMBODIMENTS

Hereinafter, embodiments are described in detail with reference to the accompanying drawings. The following embodiments may be implemented alone or by a combination of one or more embodiments. Therefore, the disclosure is not limited to one embodiment.

Herein, a singular form of elements may include a plural form unless the context clearly indicates otherwise. Some elements illustrated in the drawings may be exaggerated for clarity. In embodiments, terms indicating an order such first, second, and nth may be used merely to facilitate description, and are not intended to limit embodiments to the described order.

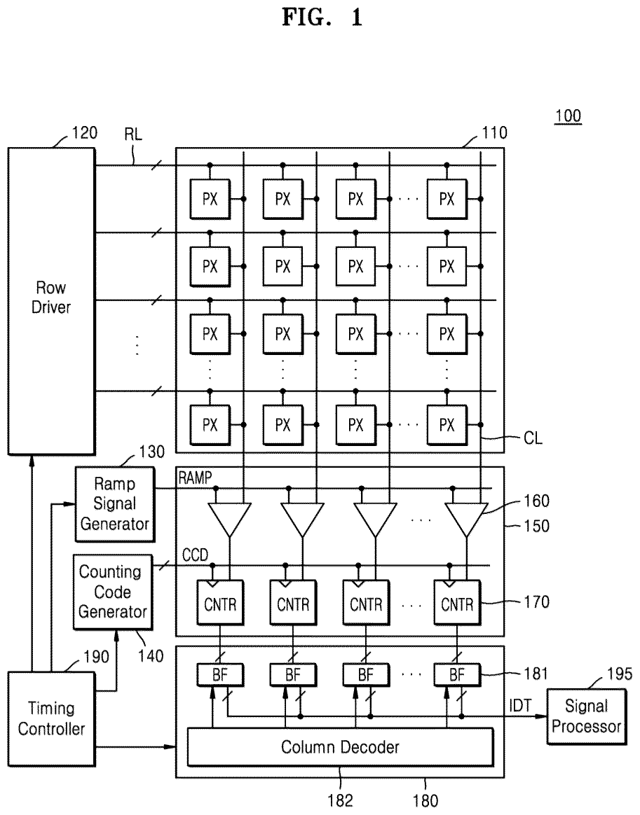

FIG. 1 is a block diagram illustrating an image sensor 100 according to an embodiment.

As shown in FIG. 1, the image sensor 100 may include a pixel array 110, a row driver 120, a ramp signal generator 130, a counting code generator 140, an analog-to-digital converter (ADC) circuit 150, a data output circuit 180, and a timing controller 190. The image sensor 100 may further include a signal processor 195. An element including the ADC circuit 150 and the data output circuit 180 may be referred to as a readout circuit.

The pixel array 110 may include a plurality of row lines RL, a plurality of column lines CL, and a plurality of pixels PX, which are connected to the plurality of row lines RL and the plurality of column lines CL and are arranged in rows and columns. The plurality of pixels PX may each include an active pixel sensor (APS).

Each of the plurality of pixels PX may include at least one photoelectric conversion element, may sense light using the photoelectric conversion element and may output an image signal, which may be an electrical signal based on the sensed light. For example, the photoelectric conversion element may include at least one of a photodiode, a photo transistor, a photogate, and a pinned photodiode.

Each of the plurality of pixels PX may sense light in a particular spectrum range. For example, a plurality of pixels PX may include a red pixel which converts light in a red spectrum range into an electrical signal, a green pixel which converts light in a green spectrum range into an electrical signal, and a blue pixel which converts light in a blue spectrum range into an electrical signal. However, the embodiments are not limited thereto, and the plurality of pixels P may further include a white pixel.

In another example, the plurality of pixels PX may include pixels based on a combination of different colors, and may include, for example, a yellow pixel, a cyan pixel, and a magenta pixel. A color filter array for transmitting light in a particular spectrum range may be disposed on the plurality of pixels PX, and a color capable of being sensed by a corresponding pixel may be determined based on a color filter disposed on each of the plurality of pixels PX. However, embodiments are not limited thereto. In some embodiments, a photoelectric conversion element may convert light in a particular wavelength band into an electrical signal based on a level of an electrical signal applied thereto.

In some embodiments, each of the plurality of pixels PX may have a dual conversion gain. The dual conversion gain may include a low conversion gain and a high conversion gain. Here, a conversion gain may denote a ratio at which electric charge accumulated in a floating diffusion node (or, for example, a floating diffusion region) is converted into a voltage. Electric charge generated by the photoelectric conversion element may be transferred to and accumulated in a floating diffusion node FD, and electric charge accumulated in the floating diffusion node FD may be converted into a voltage based on a conversion gain. In embodiments, the conversion gain may vary based on a capacitance of the floating diffusion node FD, such that the conversion gain may be reduced when capacitance increases, and the conversion gain may increase when capacitance decreases.

The row driver 120 may drive the pixel array 110 by row units. The row driver 120 may decode a row control signal (for example, an address signal) received from the timing controller 190, and in response to, or based on, a decoded row control signal, the row driver 120 may select at least one row line from among row lines included in the pixel array 110.

For example, the row driver 120 may generate a selection signal which selects one row from among a plurality of rows. Also, the pixel array 110 may output a pixel signal (for example, a pixel voltage) from a row selected by the selection signal provided from the row driver 120. The pixel signal may include a reset signal and an image signal. The row driver 120 may transfer control signals, which may be for outputting the pixel signal, to the pixel array 110, and the pixel PX may operate in response to, or based on, the control signals to output the pixel signal.

The ramp signal generator 130 may generate a ramp signal (for example, a ramp voltage) where a level is raised or lowered with a particular slope, based on control by the timing controller 190. The ramp signal RAMP may be provided to each of a plurality of correlated double sampling (CDS) circuits 160 included in the ADC circuit 150.

The counting code generator 140 may generate a counting code CCD based on control by the timing controller 190. The counting code CCD may be provided to each of a plurality of counter circuits 170 (illustrated as “CNTR”). In some embodiments, the counting code generator 140 may be, or may include, a gray code generator. The counting code generator 140 may generate, as the counting code CCD, a plurality of code values having resolution based on the number of predetermined bits. For example, based on a 10-bit code being set, the counting code generator 140 may generate a counting code CCD including 1,024 code values which may sequentially increase or decrease.

The ADC circuit 150 may include the plurality of CDS circuits 160 and the plurality of counter circuits 170. The ADC circuit 150 may convert the pixel signal (for example, the pixel voltage), input from the pixel array 110, into a pixel value which may be a digital signal. Each of a plurality of pixel signals respectively received through the plurality of column lines CL may be converted into a pixel value, which may be a digital signal, based on the CDS circuit 160 and the counter circuit 170.

The CDS circuit 160 may compare the ramp signal RAMP with the pixel signal (for example, the pixel voltage) received through the column line CL and may output a comparison result as a comparison result signal. Based on a level of the ramp signal RAMP being equal to a level of the pixel signal, the CDS circuit 160 may output a comparison signal which is shifted from a first level (for example, logic high) to a second level (for example, logic low). The time at which a level of the comparison signal is shifted may be determined based on a level of the pixel signal.

The CDS circuit 160 may sample the pixel signal provided from the pixel PX based on a CDS scheme. The CDS circuit 160 may sample the reset signal received as the pixel signal, compare the reset signal with the ramp signal RAMP, and generate the comparison signal based on the reset signal. Subsequently, the CDS circuit 160 may sample an image signal correlated with the reset signal, compare the image signal with the ramp signal RAMP, and generate the comparison signal based on the image signal.

The counter circuit 170 may count the level shift time of the comparison result signal output from the CDS circuit 160 and may output a count value. In some embodiments, the counter circuit 170 may include a latch circuit and a calculation circuit. The latch circuit may receive the counting code CCD from the counting code generator 140 and the comparison signal from the CDS circuit 160, and may latch a code value of the counting code CCD at the time at which a level of the comparison signal is shifted.

The latch circuit may latch a code value corresponding to the reset signal, and for example, may latch each of a reset value and a code value corresponding to the image signal (for example, an image signal value). The calculation circuit may perform an arithmetic operation on the reset value and the image signal value to generate an image signal value from which a reset level of the pixel PX has been removed. The counter circuit 170 may output, as the pixel value, the image signal value from which the reset level has been removed.

Although FIG. 1 illustrates an example in which the image sensor 100 includes the counting code generator 140 and the counter circuit 170 includes a circuit which latches a code value of the counting code CCD received from the counting code generator 140, but embodiments are not limited thereto.

In some embodiments, the image sensor 100 may not include a separate counting code generator 140, and the counter circuit 170 may be, or may include, at least one from among an up-counter and a calculation circuit, an up/down counter, and a bit-wise inversion counter, where a count value increases sequentially, based on the counting clock signal provided from the timing controller 190.

The data output circuit 180 may temporarily store the pixel value output from the ADC circuit 150 and may then output the pixel value. The data output circuit 180 may include a plurality of column memories 181 (illustrated as “BF”) and a column decoder 182. The column memory 181 may store the pixel value received from the counter circuit 170. In some embodiments, each of the plurality of column memories 181 may be included in the counter circuit 170. A plurality of pixel values stored in the plurality of column memories 181 may be output as image data IDT, based on the control of the column memory 181.

The timing controller 190 may output a control signal to each of the row driver 120, the ramp signal generator 130, the counting code generator 140, the ADC circuit 150, and the data output circuit 180 to control an operation or timing of each of the row driver 120, the ramp signal generator 130, the counting code generator 140, the ADC circuit 150, and the data output circuit 180.

The signal processor 195 may perform noise reduction processing, gain adjustment, waveform normalization processing, interpolation processing, white balance processing, gamma processing, and binning on the image data IDT. In some embodiments, the signal processor 195 may be included in an external processor outside the image sensor 100.

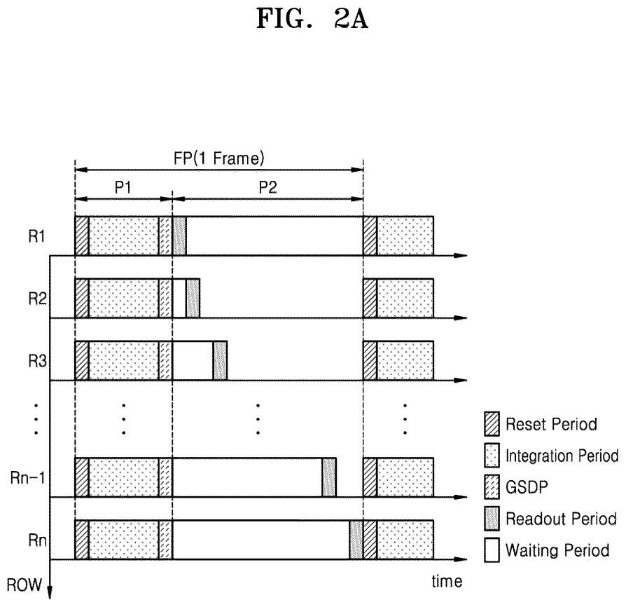

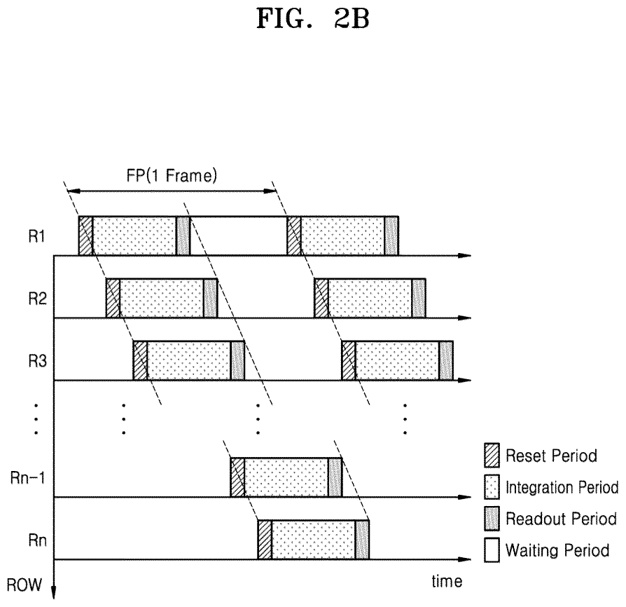

FIGS. 2A and 2B are diagrams of an operation of an image sensor 100 according to an embodiment.

In detail, FIGS. 2A and 2B are timing diagrams showing an operation of a global shutter mode (which may be referred to as a global shutter scheme) and an operation of a rolling shutter mode (which may be referred to as a rolling shutter scheme).

Referring to FIGS. 1 and 2A, the image sensor 100 may operate in the global shutter mode. One frame period FP may include a first period P1 and a second period P2.

In the first period P1, the plurality of pixels PX of the pixel array 110 (for example, a plurality of rows (for example, first to nth rows R1 to Rn)) of the pixel array 110 may perform a reset operation, an exposure operation, and a global signal dumping operation. In the second period P2, the plurality of rows of the pixel array 110 may sequentially perform a read operation. The second period P2 may be referred to as a frame readout period.

The first period P1 may include a reset period, an integration period, and a global signal dumping period (illustrated as “GSDP”). The plurality of pixels PX may perform a reset operation which includes removing electric charge accumulated in the photodiode (and the floating diffusion node) during the reset period, and may perform an integration operation which includes generating and accumulating photocharge corresponding to a received light signal by using the photodiode during the integration period. During the global signal dumping period, each of the plurality of pixels PX may respectively store the reset signal based on a reset level of the floating diffusion node and an image signal, corresponding to the photocharge accumulated in the photodiode, in at least two capacitors included therein.

In the second period P2, a rolling readout operation may be performed in which readout operations may be sequentially performed during the readout period. For example, a readout operation may be performed on the first row R1 of the pixel array 110, and then a readout operation subsequent thereto may be performed on the second row R2. Also, the readout operation may be performed on the second row R2, and then a readout operation subsequent thereto may be performed on the third row R3. In a readout operation, the reset signal and the image signal respectively stored in the at least two capacitors may be output as pixel signals from each pixel PX in the global signal dumping period.

Referring to FIGS. 1 and 2B, the image sensor 100 may operate in the rolling shutter mode. In one frame period FP, the plurality of rows (for example, the first to nth rows R1 to Rn) of the pixel array 110 may sequentially perform a reset operation, an exposure operation, and a readout operation.

Pixels PX of one row may perform a reset operation during the reset period and may perform an integration operation during the integration period, and during the readout period, each of the pixels PX may output, as a pixel signal, the reset signal (for example, a reset voltage) corresponding to the reset level of the floating diffusion node and an image signal (for example, an image voltage) corresponding to photocharge generated by the photodiode. Readout periods of the plurality of rows of the pixel array 110 may not overlap each other. After the readout period, pixels PX of one row may again perform a reset operation after a waiting period. In an embodiment, the waiting period may be set such that a readout period of a next frame period of at least one row (for example, the first row R1 and the second row R2) initially read out in the frame period FP does not overlap a readout period of a current frame period of at least one other row (for example, an (n−1)^{th} row Rn−1 and the n^{th} row Rn) most recently read out in the frame period FP. As described above, the image sensor 100 according to an embodiment may selectively operate in the global shutter mode or the rolling shutter mode.

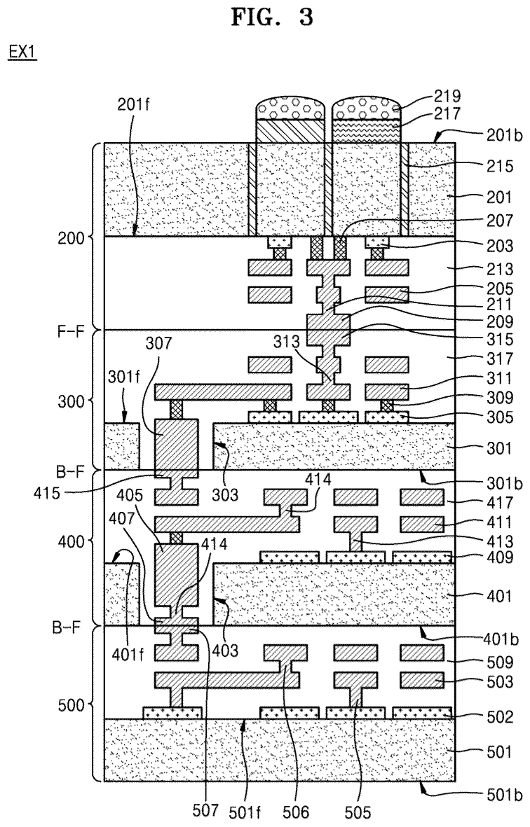

FIG. 3 is a schematic cross-sectional view of a structure of an image sensor EX1 according to an embodiment.

In detail, the image sensor EX1 may be an example of the image sensor 100 of FIG. 1. The image sensor EX1 may include the pixel PX of FIG. 1. The image sensor EX1 may include a top layer 200, a first middle layer 300, a second middle layer 400, and a bottom layer 500.

In the image sensor EX1, the second middle layer 400, the first middle layer 300, and the top layer 200 may be stacked on the bottom layer 500. The image sensor EX1 may include four layers in which the second middle layer 400, the first middle layer 300, and the top layer 200 are stacked on the bottom layer 500. The image sensor EX1 may include four layers in which the bottom layer 500, the second middle layer 400, the first middle layer 300, and the top layer 200 are bonded to each other.

Hereinafter, a transistor described below may be, or may include, at least one of a planar transistor, a multi bridge channel (MBC) transistor, a gate all around (GAA) transistor, and a fin field effect transistor (FinFET).

The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first substrate 201 may be a silicon substrate. The first substrate 201 may include a first front-side surface 201f and a first backside surface 201b corresponding to the first front-side surface 201f. Photodiodes may be disposed in the first substrate 201. In some embodiments, one photodiode may be disposed to correspond to one color filter 217 and one lens 219. In some embodiments, a plurality of photodiodes (for example, two or four photodiodes) may be disposed to correspond to one color filter 217 and one lens 219.

The first transistor 203 may be formed on the first front-side surface 201f. In FIG. 3, a first source and drain region included in the first transistor 203 may be formed in the first substrate 201, but embodiments are not limited thereto.

The first contact plug 207 and the first wiring layer 205 may be connected to the first transistor 203. The first contact plug 207 may include a metal layer (for example, a tungsten layer). The first wiring layer 205 may be connected to the first via plug 211. The first contact plug 207 and the first wiring layer 205 may be connected to the first front-side bonding pad 209. The first wiring layer 205, the first front-side bonding pad 209, and the first via plug 211 may include a metal layer (for example, a copper layer).

The first middle layer 300 may include a second substrate 301, a plurality of second transistors 305, a second backside bonding via 307, a second wiring layer 311, a second contact plug 309, a second front-side bonding pad 315, a second via plug 313, and a second insulation layer 317. In embodiments, a via as described herein may be referred to as, for example, a through via or a through-hole via.

The first front-side bonding pad 209 included in the top layer 200 may be bonded to the second front-side bonding pad 315 included in the first middle layer 300. The first insulation layer 213 included in the top layer 200 may be bonded to the second insulation layer 317 included in the first middle layer 300. The top layer 200 and the first middle layer 300 may include a boundary surface F-F at which a front-side surface F is bonded to a front-side surface F.

The second substrate 301 may be a silicon substrate. The second substrate 301 may include a second front-side surface 301f and a second backside surface 301b corresponding to the second front-side surface 301f. The second transistor 305 may be formed on the second front-side surface 301f. In FIG. 3, a second source and drain region included in the second transistor 305 may be formed in the second substrate 301, but embodiments are not limited thereto.

A hole 303 passing through the second front-side surface 301f and the second backside surface 301b may be formed in the second substrate 301. The second backside bonding via 307 insulated by the second insulation layer 317 may be formed in the hole 303. In embodiments, a hole as described herein may be referred to as, for example, a through-via hole or a through hole.

The second contact plug 309 and the second wiring layer 311 may be connected to the second transistor 305. The second contact plug 309 may include a metal layer (for example, a tungsten layer). The second contact plug 309 and the second wiring layer 311 may be connected to the second front-side bonding pad 315 and the second backside bonding via 307. The second backside bonding via 307, the second wiring layer 311, the second front-side bonding pad 315, and the second via plug 313 may include a metal layer (for example, a copper layer).

The second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

The second backside bonding via 307 included in the first middle layer 300 may be bonded to the third front-side bonding pad 415 included in the second middle layer 400. The second insulation layer 317 included in the first middle layer 300 and the second substrate 301 may be bonded to the third insulation layer 417 included in the second middle layer 400. The first middle layer 300 and the second middle layer 400 may include a boundary surface B-F at which a backside surface B is bonded to a front-side surface F.

The third substrate 401 may be a silicon substrate. Although FIG. 3 illustrates an example in which the third substrate 401 is a silicon substrate, embodiments are not limited thereto. For example, in some embodiments, the third substrate 410 may be a silicon on insulator (SOI) substrate. The third substrate 401 may include a third front-side surface 401f and a third backside surface 401b corresponding to the third front-side surface 401f. The third transistor 409 may be formed on the third front-side surface 401f. In FIG. 3, a third source and drain region included in the third transistor 409 may be formed in the third substrate 401, but embodiments are not limited thereto.

A hole 403 passing through the third front-side surface 401f and the third backside surface 401b may be formed in the third substrate 401. The third via 405 insulated by the third insulation layer 417 may be formed in the hole 403. The third via 405 may be connected to the third backside bonding pad 407 through the third via plug 414.

The third contact plug 413 and the third wiring layer 411 may be connected to the third transistor 409. The third contact plug 413 may include a metal layer (for example, a tungsten layer). The third contact plug 413 and the third wiring layer 411 may be connected to the third front-side bonding pad 415 and the third backside bonding pad 407. The third backside bonding via 407, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third backside bonding pad 407 included in the second middle layer 400 may be bonded to the fourth front-side bonding pad 507 included in the bottom layer 500. The third insulation layer 417 included in the second middle layer 400 and the third substrate 401 may be bonded to the fourth insulation layer 509 included in the bottom layer 500. The second middle layer 400 and the bottom layer 500 may include a boundary surface B-F at which a backside surface B is bonded to a front-side surface F.

The fourth substrate 501 may be a silicon substrate. The fourth substrate 501 may include a fourth front-side surface 501f and a fourth backside surface 501b corresponding to the fourth front-side surface 501f. The fourth transistor 502 may be formed on the fourth front-side surface 501f. In FIG. 3, a fourth source and drain region included in the fourth transistor 502 may be formed in the fourth substrate 501, but embodiments are not limited thereto.

The fourth contact plug 505 and the fourth wiring layer 503 may be connected to the fourth transistor 502. The fourth contact plug 505 may include a metal layer (for example, a tungsten layer). The fourth wiring layer 503 may be connected to the fourth front-side bonding pad 507 through the fourth via plug 506. The fourth contact plug 505 and the fourth wiring layer 503 may be connected to the fourth front-side bonding pad 507. The fourth front-side bonding pad 507, the fourth wiring layer 503, and the fourth contact plug 506 may include a metal layer (for example, a copper layer).

In the image sensor EX1 described above, the first front-side bonding pad 209 included in the top layer 200 may be bonded to the second front-side bonding pad 315 included in the first middle layer 300, and the top layer 200 and the first middle layer 300 may include a boundary surface F-F at which a front-side surface F is bonded to a front-side surface F.

In the image sensor EX1 described above, the second backside bonding via 307 included in the first middle layer 300 may be bonded to the third front-side bonding pad 415 included in the second middle layer 400. The first middle layer 300 and the second middle layer 400 may include a boundary surface B-F at which a backside surface B is bonded to a front-side surface F.

In the image sensor EX1 described above, the third backside bonding pad 407 included in the second middle layer 400 may be bonded to the fourth front-side bonding pad 507 included in the bottom layer 500. The second middle layer 400 and the bottom layer 500 may include a boundary surface B-F at which a backside surface B is bonded to a front-side surface F.

As described above, in the image sensor EX1, the top layer 200, the first middle layer 300, the second middle layer 400, and the bottom layer 500 may be bonded to each other through a bonding pad or a bonding via, and elements of a pixel circuit may be disposed apart from one another in the top layer 200, the first middle layer 300, the second middle layer 400, and the bottom layer 500. In this case, the image sensor EX1 may allow a reduction in pixel size and decreased noise.

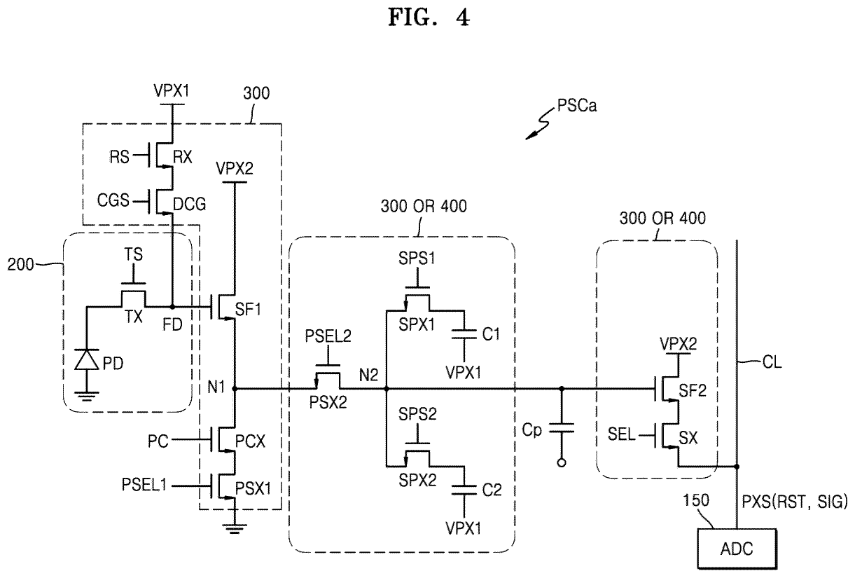

FIG. 4 is a circuit diagram of an image sensor according to an embodiment.

In detail, FIG. 4 may be a schematic circuit diagram of the pixel PX of the image sensor 100 of FIG. 1. FIG. 4 may be a circuit diagram of a schematic pixel PX which may be used to perform an operation of the global shutter mode of the image sensor 100 described above with reference to FIGS. 1 and 2A. FIG. 4 may be a schematic circuit diagram of the pixel PX of the image sensor EX1 of FIG. 3.

The pixel PX may include a photodiode PD and a pixel circuit PSCa which may generate a pixel signal PXS. Although FIG. 4 illustrates an example in which one photodiode PD and one transfer transistor TX are connected to a floating diffusion node FD in the pixel circuit PSCa, embodiments are not limited thereto. For example, in some embodiments a plurality of photodiodes (for example, two or four photodiodes) and transfer transistors respectively connected to the two or four photodiodes may be connected to the floating diffusion node FD in the pixel circuit PSCa.

Control signals TS, RS, CGS, PSEL1, PSEL2, PC, SPS1, SPS2, and SEL may be applied to the pixel circuit PSCa, and at least some of the control signals may be generated by the row driver 120. The photodiode PD may generate photocharge which varies according to the intensity of light. For example, the photodiode PD may generate electric charge (e.g., an electron which is negative electric charge and a hole which is positive electric charge) in proportion to the amount of incident light.

The pixel circuit PSCa may include a plurality of transistors TX, RX, DCG, SF1, PSX1, PSX2, PCX, SPX1, SPX2, SF2, and SX, a first capacitor C1, and a second capacitor C2. Electric charge corresponding to a reset operation may be reset, or electric charge corresponding to a photocharge integration operation may accumulate in each of the first capacitor C1 and the second capacitor C2.

The pixel circuit PSCa may include a transfer transistor TX connected to the photodiode PD. In some embodiments, the photodiode PD and the transfer transistor TX may be disposed in the top layer 200 described above.

The transfer transistor TX may be connected between the photodiode PD and the floating diffusion node FD. A first terminal of the transfer transistor TX may be connected to an output terminal of the photodiode PD, and a second terminal of the transfer transistor TX may be connected to the floating diffusion node FD.

The transfer transistor TX may be turned on or off in response to, or based on, a transfer control signal TS received from the row driver 120 and may transfer photocharge, generated by the photodiode PD, to the floating diffusion node FD.

The pixel circuit PSCa may include a reset transistor RX. The reset transistor RX may reset electric charge accumulated in the floating diffusion node FD. A first pixel voltage VPX1 (which may be referred to as a source voltage) may be applied to a first terminal of the reset transistor RX, and a second terminal of the reset transistor RX may be connected to the floating diffusion node FD. The reset transistor RX may be turned on or off in response to, or based on, a reset control signal RS received from the row driver 120, and as electric charge accumulated in the floating diffusion node FD is discharged, the floating diffusion node FD may be reset.

The pixel circuit PSCa may include a conversion gain transistor DCG. The conversion gain transistor DCG may change capacitance of the floating diffusion node FD based on the conversion gain signal CGS. For example, based on the conversion gain transistor DCG being turned on, a capacitance may increase, and thus, the pixel circuit PSCa may operate with a low conversion gain. As another example, based on the conversion gain transistor DCG being turned off, a capacitance may decrease, and thus, the pixel circuit PSCa may operate with a high conversion gain.

Based on the reset transistor RX is turned on according to the reset control signal RS and the conversion gain transistor DCG is turned on according to the conversion gain signal CGS, the floating diffusion node FD may be reset based on the first pixel voltage VPX1. At this time, a reset signal corresponding to a voltage level of the floating diffusion node FD may be output.

The pixel circuit PSCa may include a first source-follow transistor SF1. A second pixel voltage VPX2 (which may be referred to as a source voltage) may be applied to a first terminal of the first source-follow transistor SF1, and in some embodiments, the second pixel voltage VPX2 applied to the first source-follow transistor SF1 may be less than or equal to the first pixel voltage VPX1. A second terminal of the first source-follow transistor SF1 may be connected to a first output node N1.

The first source-follow transistor SF1 may be a buffer amplifier and may buffer a signal based on the amount of electric charges charged in the floating diffusion node FD. An electrical potential of the floating diffusion node FD may vary depending on the amount of electric charge accumulated in the floating diffusion node FD, and the first source-follow transistor SF1 may amplify a variation of an electrical potential in the floating diffusion node FD and may output a variation-amplified electric charge to the first output node N1.

The pixel circuit PSCa may include a first precharge selection transistor PSX1 for resetting the first output node N1. For example, the pixel circuit PSCa may include a first precharge selection transistor PSX1. A first terminal of the first precharge selection transistor PSX1 may be connected to the first output node N1 through a precharge transistor PCX, and a second terminal of the first precharge selection transistor PSX1 may be connected to a ground voltage.

The first precharge selection transistor PSX1 may be turned on or off in response to, or based on, a first precharge control signal PSEL1 received from the row driver 120 and may reset the first output node N1 through the precharge transistor PCX. In some embodiments, the pixel circuit PSCa may include a plurality of precharge selection transistors for resetting the first output node N1.

For example, the pixel circuit PSCa may further include a second precharge selection transistor PSX2 in addition to the first precharge selection transistor PSX1. A first terminal of the second precharge selection transistor PSX2 may be connected to the first output node N1, and a second terminal of the second precharge selection transistor PSX2 may be connected to a second output node N2. The second precharge selection transistor PSX2 may be turned on or off in response to, or based on, a second precharge control signal PSEL2 received from the row driver 120 and may reset the first output node N1 and the second output node N2.

Although FIG. 4 illustrates an example in which the pixel PX includes two precharge selection transistors PSX1 and PSX2, embodiments are not limited thereto. For example, in some embodiments the pixel PX may include any number of precharge selection transistors, which may be transistors for resetting the first output node N1.

The pixel circuit PSCa may include a precharge transistor PCX. A first terminal of the precharge transistor PCX may be connected to the first output node N1, and a second terminal may be connected to the first precharge selection transistor PSX1. The precharge transistor PCX may operate as a current source based on a precharge control signal PC received from the row driver 120 and may precharge the first output node N1.

In some embodiments, the reset transistor RX, the conversion gain transistor DCG, the first source-follow transistor SF1, the precharge transistor PCX, and the first precharge selection transistor PSX1 may be disposed in the first middle layer 300 described above.

The pixel circuit PSCa may include a first sampling transistor SPX1. A first terminal of the first sampling transistor SPX1 may be connected to the second output node N2, and a second terminal of the first sampling transistor SPX1 may be connected to the first capacitor C1. The first sampling transistor SPX1 may be turned on or off in response to, or based on, a first sampling control signal SPS1 received from the row driver 120 and may connect the first capacitor C1 to the second output node N2.

The first pixel voltage VPX1 may be applied to a first terminal of the first capacitor C1, and the first sampling transistor SPX1 may be connected to a second terminal of the first capacitor C1. Electric charge may accumulate in the first capacitor C1 based on a switching operation of the first sampling transistor SPX1. For example, electric charge may accumulate in the first capacitor C1 based on a reset operation which includes resetting the floating diffusion node FD.

The pixel circuit PSCa may include a second sampling transistor SPX2. A first terminal of the second sampling transistor SPX2 may be connected to the second output node N2, and a second terminal of the second sampling transistor SPX2 may be connected to the second capacitor C2. The second sampling transistor SPX2 may be turned on or off in response to, or based on, a second sampling control signal SPS2 received from the row driver 120 and may connect the second capacitor C2 to the second output node N2.

The first pixel voltage VPX1 may be applied to a first terminal of the second capacitor C2, and the second sampling transistor SPX2 may be connected to a second terminal of the second capacitor C2. Electric charge may accumulate in the second capacitor C2 based on a switching operation of the second sampling transistor SPX2. For example, electric charge based on a photocharge integration operation which includes accumulating photocharge, generated by the photodiode PD, in the floating diffusion node FD may accumulate in the second capacitor C2.

Each of the first sampling transistor SPX1 and the second sampling transistor SPX2 may be a transistor for switching the first capacitor C1 and the second capacitor C2. In some embodiments, at least one of the first capacitor C1 and the second capacitor C2 may include at least one from among a metal insulator metal (MIM) capacitor, a metal oxide semiconductor (MOS) capacitor, a trench capacitor, a poly insulator poly (PIP) capacitor, and a three-dimensional (3D) capacitor.

In Although FIG. 4 illustrates an example in which the first sampling transistor SPX1 and the first capacitor C1 are connected to the second output node N2 and the second sampling transistor SPX2 and the second capacitor C2 are connected to the second output node N2, embodiments are not limited thereto. For example, in some embodiments a third sampling transistor and a third capacitor may be additionally connected to the second output node N2.

In some embodiments, the second precharge selection transistor PSX2, the first sampling transistor SPX1, the second sampling transistor SPX2, the first capacitor C1, and the second capacitor C2 may be disposed in the first middle layer 300 or the second middle layer 400 described above.

In the pixel circuit PSCa, a parasitic capacitor Cp may be connected to the second output node N2. In addition, the pixel circuit PSCa may include a second source-follow transistor SF2 and a selection transistor SX. The second pixel voltage VPX2 may be applied to a first terminal of the second source-follow transistor SF2, and the selection transistor SX may be connected to a second terminal of the second source-follow transistor SF2. The second source-follow transistor SF2 may amplify and output a variation of an electrical potential in the second output node N2.

In some embodiments, the second pixel voltage VPX2 applied to the second source-follow transistor SF2 may be less than or equal to the first pixel voltage VPX1. A first terminal of the selection transistor SX may be connected to the second source-follow transistor SF2, and a second terminal of the selection transistor SX may be connected to the column line CL. The selection transistor SX may be turned on or off in response to, or based on, the selection control signal SELS received from the row driver 120. Based on the selection transistor SX being turned on in a readout operation, a pixel signal PXS including an image signal SIG corresponding to a charge integration operation or a reset signal RST corresponding to a reset operation may be output to the column line CL.

For example, based on the first sampling transistor SPX1 being turned on and the second sampling transistor SPX2 being turned off while the selection transistor SX is operating in an on state, the reset signal RST corresponding to electric charge accumulated in the first capacitor C1 may be output. As another example, based on the second sampling transistor SPX2 being turned on and the first sampling transistor SPX1 being turned off while the selection transistor SX is operating in an on state, the image signal SIG corresponding to electric charge accumulated in the second capacitor C2 may be output.

In an embodiment, the image signal SIG may be additionally output. For example, based on a method described above, a first image signal corresponding to electric charge accumulated in the second capacitor C2 may be output, and then, a second image signal corresponding to electric charge accumulated in each of the first capacitor C1 and the second capacitor C2 may be additionally output.

For example, based on both of the first sampling transistor SPX1 and the second sampling transistor SPX2 operating in an on state while the selection transistor SX is operating in an on state, the second image signal corresponding to the electric charge accumulated in each of the first capacitor C1 and the second capacitor C2 may be output. Based on both of the first sampling transistor SPX1 and the second sampling transistor SPX2 operating in an on state, the first capacitor C1 may be connected to the second capacitor C2 in parallel. Therefore, in comparison with the first image signal, a voltage of the second image signal may decrease as a conversion gain decreases.

The first image signal and the second image signal which are read by a method described above may be selectively used to generate the image data IDT, based on an illuminance state. For example, the first image signal may be used in a low illuminance state, and the second image signal may be used in a high illuminance state.

In some embodiments, a second selection transistor may be further connected to the first output node N1 of the pixel circuit PSCa. In this case, the pixel PX may operate in the rolling shutter mode. In a case in which the pixel PX operates in the rolling shutter mode, the selection transistor SX may be turned off and the second selection transistor may be turned on. Accordingly, the reset signal RST and the image signal SIG may be output as the pixel signal PXS to the column line CL through the second selection transistor and the first output node N1.

In some embodiments, the second source-follow transistor SF2 and the selection transistor SX may be disposed in the first middle layer 300 or the second middle layer 400 described above. In addition, an ADC circuit (for example, the ADC circuit 150 of FIG. 1) may be disposed in the bottom layer 500 described above.

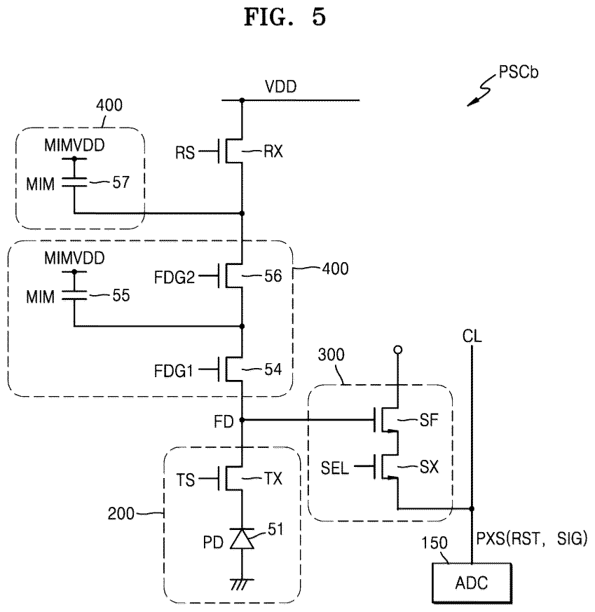

FIG. 5 is a circuit diagram of an image sensor according to an embodiment.

In detail, FIG. 5 may be a schematic circuit diagram of the pixel PX of the image sensor 100 of FIG. 1. FIG. 5 may be a circuit diagram of a schematic pixel PX which implements an operation of the rolling shutter mode of the image sensor 100 described above with reference to FIGS. 1 and 2B. FIG. 5 may be a schematic circuit diagram of the pixel PX of the image sensor EX1 of FIG. 3. The pixel PX may include a photodiode PD and a pixel circuit PSCb which generates a pixel signal PXS.

Although FIG. 5 illustrates an example in which one photodiode PD and one transfer transistor TX are connected to a floating diffusion node FD in the pixel circuit PSCb, embodiments are not limited thereto. For example, in some embodiments a plurality of photodiodes (for example, two or four photodiodes) and transfer transistors respectively connected to the two or four photodiodes may be connected to the floating diffusion node FD in the pixel circuit PSCb.

The pixel circuit PSCb may include a photoelectric conversion unit 51, a transfer transistor 52, a floating diffusion node FD, a first conversion efficiency switching transistor 54, a MIM-type first capacitor 55, a second conversion efficiency switching transistor 56, a MIM-type second capacitor 57, a reset transistor RX, a source-follow transistor SF, and a selection transistor SX.

The photoelectric conversion unit 51 may include a photodiode PD having a PN junction. The photoelectric conversion unit 51 may perform photoelectric conversion on incident light to store electric charge. The transfer transistor TX may be installed between the photoelectric conversion unit 51 and the floating diffusion node FD, and a driving signal TS may be supplied to a gate electrode of the transfer transistor TX.

Based on the driving signal TS having a high level, the transfer transistor TX may be turned on, and the electric charge stored in the photoelectric conversion unit 51 may be transferred to the floating diffusion node FD through the transfer transistor TX. The floating diffusion node FD may be a floating diffusion region and may function as a storage unit which temporarily stores electric charge overflowing from the photoelectric conversion unit 51. In some embodiments, the photoelectric conversion unit 51 including the photodiode PD and the transfer transistor TX may be disposed in the top layer 200 described above.

The first conversion efficiency switching transistor 54 may be provided between the floating diffusion node FD and the MIM-type first capacitor 55. A source voltage MIMVDD may be connected to one end of the MIM-type first capacitor 55. A driving signal FDG may be supplied to the first conversion efficiency switching transistor 54. The first conversion efficiency switching transistor 54 may correspond to the conversion gain transistor (for example, the conversion gain transistor DCG of FIG. 4) described above.

Based on a first driving signal FDG1 reaching a high level, the first conversion efficiency switching transistor 54 may be turned on, and electric charge from the floating diffusion node FD may be transferred to the MIM-type first capacitor 55 using the first conversion efficiency switching transistor 54. The MIM-type first capacitor 55 may temporarily store electric charge overflowing from the photoelectric conversion unit 51.

Based on the first conversion efficiency switching transistor 54 being turned on, a region storing electric charge may be a region where the floating diffusion node FD is coupled to the MIM-type first capacitor 55, and electric charge generated by the photoelectric conversion unit 51 may be converted into a voltage. The first conversion efficiency switching transistor 54 may function as a conversion efficiency switching transistor which switches conversion efficiency.

The second conversion efficiency switching transistor 56 may be provided between the MIM-type first capacitor 55 and the MIM-type second capacitor 57. The source voltage MIMVDD may be connected to one end of the MIM-type second capacitor 57. A second driving signal FDG2 may be supplied to the second conversion efficiency switching transistor 56. Based on the second driving signal FDG2 reaching a high level, the second conversion efficiency switching transistor 56 may be turned on, and electric charge from the MIM-type first capacitor 55 may be transferred to the MIM-type second capacitor 57 using the second conversion efficiency switching transistor 56. The second conversion efficiency switching transistor 56 may correspond to the conversion gain transistor (for example, the conversion gain transistor DCG of FIG. 4) described above.

Based on the second conversion efficiency switching transistor 56 being turned on, a region storing electric charge may be a region where the floating diffusion node FD, the MIM-type first capacitor 55, and the MIM-type second capacitor 57 are coupled to each other. The second conversion efficiency switching transistor 56 may function as a conversion efficiency switching transistor which switches conversion efficiency.

The first conversion efficiency switching transistor 54 and the second conversion efficiency switching transistor 56 may be transistors for switching the MIM-type first capacitor 55 and the MIM-type second capacitor 57. Although the example of the pixel circuit PSCb is described above as including the MIM-type first capacitor 55 and the MIM-type second capacitor 57, embodiments are not limited thereto. For example, in some embodiments the pixel circuit PSCb may include at least one of a MOS capacitor, a trench capacitor, a PIP capacitor, and a 3D capacitor.

In some embodiments, the first conversion efficiency switching transistor 54, the second conversion efficiency switching transistor 56, the MIM-type first capacitor 55, and the MIM-type second capacitor 57 may be disposed in the second middle layer 400 described above.

Each of the MIM-type first capacitor 55 and the MIM-type second capacitor 57 may implement high capacitance without sacrificing an area of a substrate (for example, silicon substrate) surface where a pixel transistor is disposed and may have capacitance which is higher than a capacitance of the floating diffusion node FD.

The reset transistor RX may be connected between a power source VDD and the MIM-type second capacitor 57, and a driving signal RS (which may be referred to as a control signal) may be supplied to the reset transistor RX. Based on the driving signal RS being set to a high level, the reset transistor RX may be turned on and an electrical potential of the MIM-type second capacitor 57 may be reset to a source voltage level. In some embodiments, the reset transistor RX may be disposed in the first middle layer 300 or the second middle layer 400 described above.

The source-follow transistor SF may be an amplification transistor. A gate electrode of the source-follow transistor SF may be connected to the floating diffusion node FD, and a drain may be connected to the power source VDD. The selection transistor SX may be connected between a source of the source-follow transistor SF and a vertical signal line CL, and a driving signal SEL may be supplied to the selection transistor SX.

Based on the driving signal SEL being set to a high level, the selection transistor SX may be turned on and the pixel may be in a selection state. Therefore, a pixel signal output from the source-follow transistor SF may be output to the vertical signal line CL through the selection transistor SX. The pixel signal may be output to an ADC circuit (for example, the ADC circuit 150 of FIG. 1).

The pixel circuit may include the floating diffusion node FD, the MIM-type first capacitor 55, and the MIM-type second capacitor 57, and the capacitors may be serially connected with each other, whereby a conversion efficiency of converting electric charge generated by the photoelectric conversion unit 51 into a voltage may be selected from among three conversion efficiencies. High conversion efficiency HCG may be implemented using the floating diffusion node FD. Middle conversion efficiency MCG may be implemented using a combination of the floating diffusion node FD and the MIM-type first capacitor 55.

Low conversion efficiency LCG may be implemented using a combination of the floating diffusion node FD, the MIM-type first capacitor 55, and the MIM-type second capacitor 57. Based on the transfer transistor 52 being turned on, electric charge accumulated in the photoelectric conversion unit 51 may be transferred to the floating diffusion node FD, according to the high conversion efficiency HCG, the floating diffusion node FD and the MIM-type first capacitor 55, according to the middle conversion efficiency MCG, and the floating diffusion node FD, the MIM-type first capacitor 55, and the MIM-type second capacitor 57, according to the low conversion efficiency LCG.

In some embodiments, the source-follow transistor SF and the selection transistor SX may be disposed in the first middle layer 300 described above. In addition, an ADC circuit (for example, the ADC circuit 150 of FIG. 1) may be disposed in the bottom layer 500 described above.

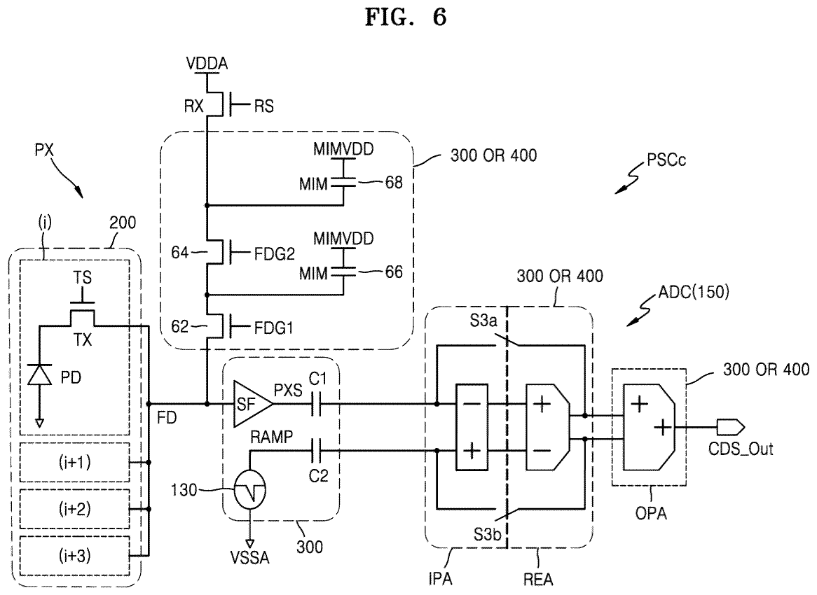

FIG. 6 is a circuit diagram of an image sensor according to an embodiment.

As shown in FIG. 6, a circuit of an image sensor may include a digital pixel sensor DPS including an ADC circuit (for example, the ADC circuit 150 of FIG. 1). FIG. 6 may be a circuit diagram of a schematic pixel PX which implements an operation of the rolling shutter mode of the image sensor 100 described above with reference to FIGS. 1 and 2B. In the description below with reference to FIG. 6, description which is redundant or duplicative of the descriptions of FIG. 1 may be briefly given or omitted.

The pixel PX may include a photodiode PD and a pixel circuit PSCc which generates a pixel signal PXS. The pixel PX illustrated in FIG. 6 may include a plurality of subpixels, for example a subpixel (i), a subpixel (i+1), a subpixel (i+2), a subpixel (i+3), and a subpixel (i+4) each of which may include a photodiode PD and a transfer transistor TX.

The plurality of subpixels may be connected to a floating diffusion node FD. An element including the photodiode PD and the transfer transistor TX illustrated in FIG. 6 may correspond to the subpixel (i).

The pixel circuit PSCc may include a transfer transistor TX connected to the photodiode PD. In some embodiments, the photodiode PD and the transfer transistor TX may be disposed in the top layer 200 described above.

A driving signal TS may be applied to the transfer transistor TX. Based on the driving signal TS having a high level, the transfer transistor TX may be turned on, and electric charge stored in the photodiode PD may be transferred to the floating diffusion node FD through the transfer transistor TX. In some embodiments, the plurality of subpixels connected to the floating diffusion node FD may include four subpixels, as illustrated in FIG. 6, but embodiments are not limited thereto.

The floating diffusion node FD may function as a storage unit which temporarily stores electric charge transferred thereto and electric charge overflowing from the photodiode PD. In some embodiments, the photodiode PD and the transfer transistor TX may be disposed in the top layer 200 described above.

A first conversion efficiency switching transistor 62 may be connected to the floating diffusion node FD. The first conversion efficiency switching transistor 62 may be provided between the floating diffusion node FD and an MIM-type first capacitor 66. A source voltage MIMVDD may be connected to one end of the MIM-type first capacitor 66. A first driving signal FDG1 may be supplied to the first conversion efficiency switching transistor 62. The first conversion efficiency switching transistor 62 may correspond to the conversion gain transistor (for example, the conversion gain transistor DCG of FIG. 4) described above.

Based on the first driving signal FDG1 reaching a high level, the first conversion efficiency switching transistor 62 may be turned on, and electric charge from the floating diffusion node FD may be transferred to the MIM-type first capacitor 66 using the first conversion efficiency switching transistor 62. The MIM-type first capacitor 66 may temporarily store electric charge overflowing from the photodiode PD.

Based on the first conversion efficiency switching transistor 62 being turned on, a region storing electric charge may be a region where the floating diffusion node FD is coupled to the MIM-type first capacitor 66, and electric charge generated by the photodiode PD may be converted into a voltage. The first conversion efficiency switching transistor 62 may function as a conversion efficiency switching transistor which switches conversion efficiency.

A second conversion efficiency switching transistor 64 may be connected to the first conversion efficiency switching transistor 62. The second conversion efficiency switching transistor 64 may be provided between the MIM-type first capacitor 66 and an MIM-type second capacitor 68. A source voltage MIMVDD may be connected to one end of the MIM-type second capacitor 68. A second driving signal FDG2 may be supplied to the second conversion efficiency switching transistor 64. Based on the second driving signal FDG2 reaching a high level, the second conversion efficiency switching transistor 64 may be turned on, and electric charge from the MIM-type first capacitor 66 may be transferred to the MIM-type second capacitor 68 using the second conversion efficiency switching transistor 64. The second conversion efficiency switching transistor 64 may correspond to the conversion gain transistor described above.

Based on the second conversion efficiency switching transistor 64 being turned on, a region storing electric charge may be a region where the floating diffusion node FD, the MIM-type first capacitor 66, and the MIM-type second capacitor 68 are coupled to each other. The second conversion efficiency switching transistor 64 may function as a conversion efficiency switching transistor which switches conversion efficiency.

The first conversion efficiency switching transistor 62 and the second conversion efficiency switching transistor 64 may be transistors for switching the MIM-type first capacitor 66 and the MIM-type second capacitor 68.

Although the example of the pixel circuit PSCc described above includes the MIM-type first capacitor 66 and the MIM-type second capacitor 68, embodiments are not limited thereto. For example, in some embodiments the pixel circuit PSCc may include at least one of a MOS capacitor, a trench capacitor, a PIP capacitor, and a 3D capacitor.

In some embodiments, the first conversion efficiency switching transistor 62, the second conversion efficiency switching transistor 64, the MIM-type first capacitor 66, and the MIM-type second capacitor 68 may be disposed in the first middle layer 300 or the second middle layer 400 described above.

Each of the MIM-type first capacitor 66 and the MIM-type second capacitor 68 may implement high capacitance without sacrificing an area of a surface of substrate (for example, a silicon substrate) where a pixel transistor is disposed and may have capacitance which is higher than a capacitance of the floating diffusion node FD.

The reset transistor RX may be connected between a power source VDD and the MIM-type second capacitor 57, and a driving signal RS (which may be referred to as a control signal) may be supplied to the reset transistor RX. Based on the driving signal RS being set to a high level, the reset transistor RX may be turned on and an electrical potential of the floating diffusion node FD may be reset to a source voltage level.

In some embodiments, the first conversion efficiency switching transistor 62, the second conversion efficiency switching transistor 64, the MIM-type first capacitor 66, and the MIM-type second capacitor 68 may be disposed in the first middle layer 300 or the second middle layer 400 described above.

The floating diffusion node FD may be connected to the source-follow transistor SF. Electric charge stored in the floating diffusion node FD may be amplified by the source-follow transistor SF, and thus, a pixel signal PXS (for example, a pixel voltage) may be output. The pixel voltage may be stored in a first capacitor C1. A ramp signal generator 130 may generate a ramp voltage RAMP. The ramp voltage RAMP may be stored in a second capacitor C2. In some embodiments, the source-follow transistor SF, the ramp signal generator 130, the first capacitor C1, and the second capacitor C2 may be disposed in the first middle layer 300 described above.

The first capacitor C1 and the second capacitor C2 may be connected to an ADC circuit 150. The ADC circuit 150 may convert the pixel signal PXS into a digital value. The ADC circuit 150 may respectively convert a reset signal and an image signal, received as the pixel signal PXS, into a reset value and an image value which are digital signals.

The ADC circuit 150 may include a CDS circuit (for example, the CDS circuit 160 of FIG. 1) including a comparator. The comparator may be, or may include, an operational transconductance amplifier (OTA) (which may be referred to as a differential amplifier). The ADC circuit 150 may include an input stage IPA of the OTA (which may be referred to as a first stage of the OTA), an amplification stage REA of the OTA, and an output stage OPA of the OTA (which may be referred to as a second stage of the OTA). The ADC circuit 150 may include a plurality of switches S3a and S3b. In some embodiments, the first capacitor C1 and the second capacitor C2 may be included in the ADC circuit 150.

The ADC circuit 150 may compare the pixel signal PXS with the ramp signal RAMP received from the ramp signal generator 130. The plurality of switches S3a and S3b may be connected to a feedback line which connects the input stage IPA of the OTA to the amplification stage REA of the OTA and may remove an offset of the comparator. The ADC circuit 150 may transfer a CDS signal through the output stage OPA of the OTA.

In some embodiments, the input stage IPA of the OTA included in the ADC circuit 150, the amplification stage REA of the OTA, and the output stage OPA of the OTA may be disposed in the first middle layer 300 or the second middle layer 400 described above. In some embodiments, at least one of a reset transistor RX and circuit elements (for example, additional transistors needed for driving the pixel PX such as a counter circuit (for example, the counter circuit 170 of FIG. 1) or a data output circuit 180) included in the pixel circuit PSCc of the image sensor may be disposed in the bottom layer 500 described above.

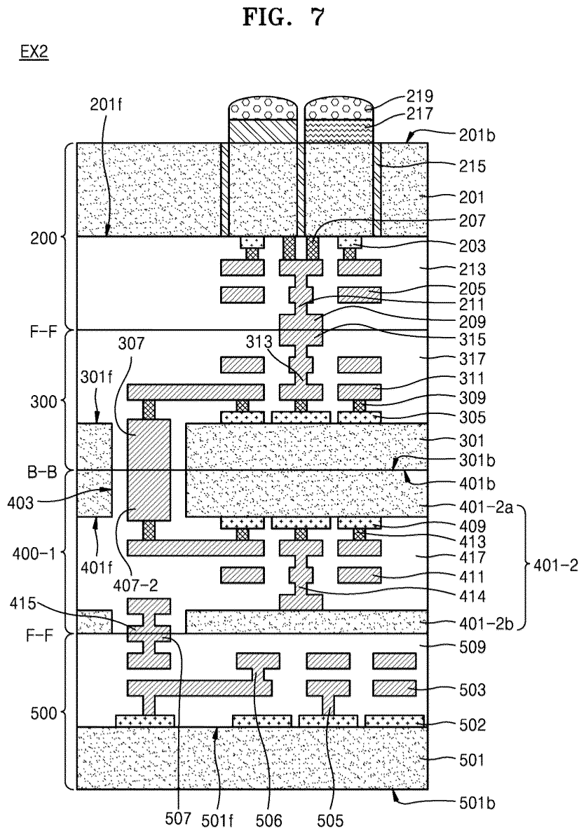

FIG. 7 is a schematic cross-sectional view of a structure of an image sensor EX2 according to an embodiment.

For example, the image sensor EX2 may be an example of the image sensor 100 of FIG. 1, according to embodiments. The image sensor EX2 may include the pixel PX of FIG. 1. In embodiments, the image sensor EX2 may be similar to the image sensor EX1 of FIG. 3 described above, except that the image sensor EX2 may include a second middle layer 400-1 as shown in FIG. 7. In the description below with reference to FIG. 7, description which is redundant or duplicative of the descriptions of FIG. 3 may be briefly given or omitted.

The image sensor EX2 may include a top layer 200, a first middle layer 300, the second middle layer 400-1, and a bottom layer 500. The image sensor EX2 may include four layers in which the bottom layer 500, the second middle layer 400-1, the first middle layer 300, and the top layer 200 are bonded to each other.

A first front-side bonding pad 209 included in the top layer 200 may be bonded to a second front-side bonding pad 315 included in the first middle layer 300. A first insulation layer 213 included in the top layer 200 may be bonded to a second insulation layer 317 included in the first middle layer 300. The top layer 200 and the first middle layer 300 may include a boundary surface F-F at which a front-side surface F is bonded to a front-side surface F.

The second middle layer 400 may include a third substrate 401-2, a plurality of third transistors 409, a third backside bonding via 407-2, a third wiring layer 411, a third contact plug 413, a third front-side bonding pad 415, a third via plug 414, and a third insulation layer 417. The third substrate 401-2 may include a lower substrate layer 401-2a and an upper substrate layer 401-2b. The lower substrate layer 401-2a and the upper substrate layer 401-2b may each include a silicon substrate. Also, the lower substrate layer 401-2a and the upper substrate layer 401-2b may each include an SOI substrate.

The second backside bonding via 307 included in the first middle layer 300 may be bonded to the third backside bonding via 407-2 included in the second middle layer 400-1. The second insulation layer 317 included in the first middle layer 300 and the second substrate 301 may be bonded to the lower substrate layer 401-2a included in the second middle layer 400-1 and the third insulation layer 417. The first middle layer 300 and the second middle layer 400-1 may include a boundary surface B-B at which a backside surface B is bonded to a backside surface B.

The lower substrate layer 401-2a and the upper substrate layer 401-2b each included in the third substrate 401-2 may each be a silicon layer. The lower substrate layer 401-2a may include a third front-side surface 401f and a third backside surface 401b corresponding to the third front-side surface 401f. A third transistor 409 may be formed on the third front-side surface 401f. In the example illustrated in FIG. 7, a third source and drain region included in the third transistor 409 may be formed in the third substrate 401-2, but embodiments are not limited thereto.

A hole 403 passing through the third front-side surface 401f and the third backside surface 401b may be formed in the lower substrate layer 401-2a. The third backside bonding via 407-2 insulated by the third insulation layer 417 may be formed in the hole 403. The third backside bonding via 407-2 may be connected to the third front-side bonding pad 415 through the third contact plug 413, the third via plug 414, and the third wiring layer 411.

The third contact plug 413 and the third wiring layer 411 may be connected to the third transistor 409. The third contact plug 413 may include a metal layer (for example, a tungsten layer). The third contact plug 413 and the third wiring layer 411 may be connected to the third front-side bonding pad 415. The third front-side bonding pad 415, the third wiring layer 411, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third front-side bonding pad 415 included in the second middle layer 400-1 may be bonded to the fourth front-side bonding pad 507 included in the bottom layer 500. The third insulation layer 417 included in the second middle layer 400-1 and the lower substrate layer 401-2b may be bonded to the fourth insulation layer 509 included in the bottom layer 500. The second middle layer 400-1 and the bottom layer 500 may include a boundary surface F-F at which a front-side surface F is bonded to a front-side surface F.

In the image sensor EX2 described above, the first front-side bonding pad 209 included in the top layer 200 may be bonded to the second front-side bonding pad 315 included in the first middle layer 300, and the top layer 200 and the first middle layer 300 may include a boundary surface F-F at which a front-side surface F is bonded to a front-side surface F.

In the image sensor EX2 described above, the second backside bonding via 307 included in the first middle layer 300 may be bonded to the third backside bonding via 407-2 included in the second middle layer 400-1. The first middle layer 300 and the second middle layer 400-1 may include a boundary surface B-B at which a backside surface B is bonded to a backside surface B.

In the image sensor EX2 described above, the third front-side bonding pad 415 included in the second middle layer 400 may be bonded to the fourth front-side bonding pad 507 included in the bottom layer 500. The second middle layer 400-1 and the bottom layer 500 may include a boundary surface F-F at which a front-side surface F is bonded to a front-side surface F.

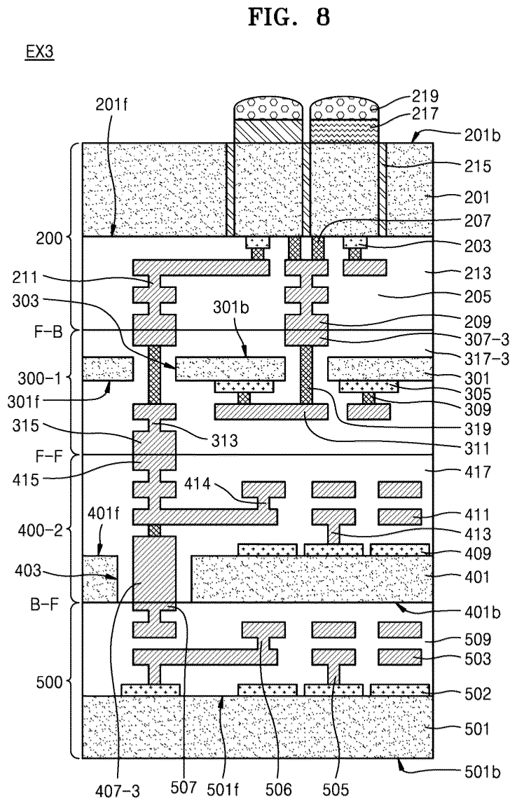

FIG. 8 is a schematic cross-sectional view of a structure of an image sensor EX3 according to an embodiment.

For example, the image sensor EX3 may be an example of the image sensor 100 of FIG. 1, according to embodiments. The image sensor EX3 may include the pixel PX of FIG. 1. In embodiments, the image sensor EX3 may be similar to the image sensor EX1 of FIG. 3 described above, except that the image sensor EX3 may include a first middle layer 300-1 and a second middle layer 400-2 as shown in FIG. 8. In the description below with reference to FIG. 8, description which is redundant or duplicative of the descriptions of FIG. 3 may be briefly given or omitted.

The image sensor EX3 may include four layers in which a bottom layer 500, the second middle layer 400-2, the first middle layer 300-1, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-1 may include a second substrate 301, a plurality of second transistors 305, a second backside bonding pad 307-3, a second wiring layer 311, a second contact plug 309, a second front-side bonding pad 315, a second via plug 313, a first connection via plug 319, a second front-side bonding pad 315, and a second insulation layer 317-3.

A first front-side bonding pad 209 included in the top layer 200 may be bonded to a second backside bonding pad 307-3 included in the first middle layer 300-1. A first insulation layer 213 included in the top layer 200 may be bonded to a second insulation layer 317-3 included in the first middle layer 300-1. The top layer 200 and the first middle layer 300-1 may include a boundary surface F-B at which a front-side surface F is bonded to a backside surface B.

The second substrate 301 may be a silicon substrate. The second substrate 301 may include a second front-side surface 301f and a second backside surface 301b corresponding to the second front-side surface 301f. The second transistor 305 may be formed on the second front-side surface 301f. In the example illustrated in FIG. 8, a second source and drain region included in the second transistor 305 may be formed in the second substrate 301, but embodiments are not limited thereto.

The second contact plug 309 and the second wiring layer 311 may be connected to the second transistor 305. The second contact plug 309 may include a metal layer (for example, a tungsten layer). The second contact plug 309 and the second wiring layer 311 may be connected to the second front-side bonding pad 315 and the second backside bonding pad 307-3. The second backside bonding pad 307-3, the second wiring layer 311, the second front-side bonding pad 315, and the second via plug 313 may include a metal layer (for example, a copper layer).

A second insulation layer 317-3 may be further formed on a lower surface of the second substrate 301. The second insulation layer 317-3 may be connected to the third wiring layer 311 by the first connection via plug 319. The first connection via plug 319 may be longer in length than the second via plug 313 in a vertical direction. The first connection via plug 319 may include a metal layer (for example, a tungsten layer).

The second middle layer 400-2 may include a third substrate 401, a plurality of third transistors 409, a third backside bonding via 407-3, a third wiring layer 411, a third contact plug 413, a third front-side bonding pad 415, a third via plug 414, and a third insulation layer 417.

The second front-side bonding pad 315 included in the first middle layer 300-1 may be bonded to the third front-side bonding pad 415 included in the second middle layer 400-2. The second insulation layer 317-3 included in the first middle layer 300-1 may be bonded to the third insulation layer 417 included in the second middle layer 400-2. The first middle layer 300-1 and the second middle layer 400-2 may include a boundary surface F-F at which a front-side surface F is bonded to a front-side surface F.

The third substrate 401 may be a silicon substrate. The third substrate 401 may include a third front-side surface 401f and a third backside surface 401b corresponding to the third front-side surface 401f. The third transistor 409 may be formed on the third front-side surface 401f. In the example illustrated in FIG. 8, a third source and drain region included in the third transistor 409 may be formed in the third substrate 401, but embodiments are not limited thereto.

A hole 403 passing through the third front-side surface 401f and the third backside surface 401b may be formed in the third substrate 401. The third backside bonding via 407-3 insulated by the third insulation layer 417 may be formed in the hole 403.

The third contact plug 413 and the third wiring layer 411 may be connected to the third transistor 409. The third contact plug 413 may include a metal layer (for example, a tungsten layer). The third contact plug 413 and the third wiring layer 411 may be connected to the third front-side bonding pad 415 and the third backside bonding via 407-3. The third backside bonding via 407-3, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third backside bonding via 407-3 included in the second middle layer 400-2 may be bonded to the fourth front-side bonding pad 507 included in the bottom layer 500. The third insulation layer 417 included in the second middle layer 400-2 and the third substrate 401 may be bonded to the fourth insulation layer 509 included in the bottom layer 500. The second middle layer 400-2 and the bottom layer 500 may include a boundary surface B-F at which a backside surface B is bonded to a front-side surface F.

In the image sensor EX3 described above, the first front-side bonding pad 209 included in the top layer 200 may be bonded to the second backside bonding pad 307-3 included in the first middle layer 300-1, and the top layer 200 and the first middle layer 300-1 may include a boundary surface F-B at which a front-side surface F is bonded to a backside surface B.

In the image sensor EX3 described above, the second front-side bonding pad 315 included in the first middle layer 300-1 may be bonded to the third front-side bonding pad 415 included in the second middle layer 400-2. The first middle layer 300-1 and the second middle layer 400-2 may include a boundary surface F-F at which a front-side surface F is bonded to a front-side surface F.

In the image sensor EX3 described above, the third backside bonding via 407-3 included in the second middle layer 400-2 may be bonded to the fourth front-side bonding pad 507 included in the bottom layer 500. The second middle layer 400-2 and the bottom layer 500 may include a boundary surface B-F at which a backside surface B is bonded to a front-side surface F.

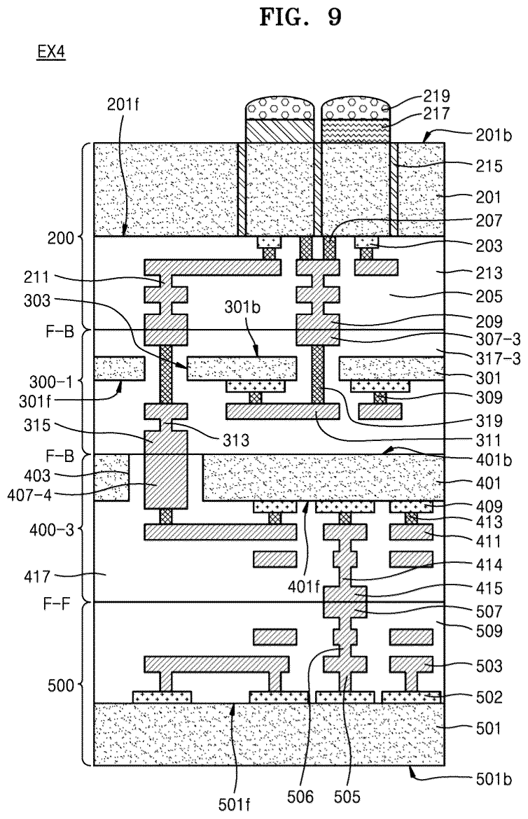

FIG. 9 is a schematic cross-sectional view of a structure of an image sensor EX4 according to an embodiment.

For example, the image sensor EX4 may be an example of the image sensor 100 of FIG. 1, according to embodiments. The image sensor EX4 may include the pixel PX of FIG. 1. In embodiments, the image sensor EX4 may be similar to the image sensor EX1 of FIG. 3 described above, except that the image sensor EX4 may include the first middle layer 300-1 and a second middle layer 400-3 as shown in FIG. 9. In the description below with reference to FIG. 9, description which is redundant or duplicative of the descriptions of FIG. 3 may be briefly given or omitted.

The image sensor EX4 may include four layers in which a bottom layer 500, the second middle layer 400-3, the first middle layer 300-1, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-1 may include a second substrate 301, a plurality of second transistors 305, a second backside bonding pad 307-3, a second wiring layer 311, a second contact plug 309, a second front-side bonding pad 315, a second via plug 313, a first connection via plug 319, a second front-side bonding pad 315, and a second insulation layer 317-3.

A first front-side bonding pad 209 included in the top layer 200 may be bonded to a second backside bonding pad 307-3 included in the first middle layer 300-1. A first insulation layer 213 included in the top layer 200 may be bonded to a second insulation layer 317-3 included in the first middle layer 300-1. The top layer 200 and the first middle layer 300-1 may include a boundary surface F-B at which a front-side surface F is bonded to a backside surface B. The first middle layer 300-1 is described above with reference to FIG. 8, and thus, redundant or duplicative description thereof is omitted.

The second middle layer 400-3 may include a third substrate 401, a plurality of third transistors 409, a third backside bonding via 407-4, a third wiring layer 411, a third contact plug 413, a third front-side bonding pad 415, a third via plug 414, and a third insulation layer 417.

The second front-side bonding pad 315 included in the first middle layer 300-1 may be bonded to the third front-side bonding via 407-4 included in the second middle layer 400-3. The second insulation layer 317-3 included in the first middle layer 300-1 may be bonded to the third insulation layer 417 included in the second middle layer 400-3. The first middle layer 300-1 and the second middle layer 400-3 may include a boundary surface F-B at which a front-side surface F is bonded to a backside surface B.

The third substrate 401 may be a silicon substrate. The third substrate 401 may include a third front-side surface 401f and a third backside surface 401b corresponding to the third front-side surface 401f. The third transistor 409 may be formed on the third front-side surface 401f. In the example illustrated in FIG. 9, a third source and drain region included in the third transistor 409 may be formed in the third substrate 401, but embodiments are not limited thereto.

A hole 403 passing through the third front-side surface 401f and the third backside surface 401b may be formed in the third substrate 401. The third backside bonding via 407-4 insulated by the third insulation layer 417 may be formed in the hole 403.

The third contact plug 413 and the third wiring layer 411 may be connected to the third transistor 409. The third contact plug 413 may include a metal layer (for example, a tungsten layer). The third contact plug 413 and the third wiring layer 411 may be connected to the third front-side bonding pad 415 and the third backside bonding via 407-4. The third backside bonding via 407-4, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third front-side bonding pad 415 included in the second middle layer 400-3 may be bonded to the fourth front-side bonding pad 507 included in the bottom layer 500. The third insulation layer 417 included in the second middle layer 400-3 may be bonded to the fourth insulation layer 509 included in the bottom layer 500. The second middle layer 400-3 and the bottom layer 500 may include a boundary surface F-F at which a front-side surface F is bonded to a front-side surface F.

In the image sensor EX4 described above, the first front-side bonding pad 209 included in the top layer 200 may be bonded to the second backside bonding pad 307-3 included in the first middle layer 300-1, and the top layer 200 and the first middle layer 300-1 may include a boundary surface F-B at which a front-side surface F is bonded to a backside surface B.

In the image sensor EX4 described above, the second front-side bonding pad 315 included in the first middle layer 300-1 may be bonded to the third backside bonding via 407-4 included in the second middle layer 400-3. The first middle layer 300-1 and the second middle layer 400-3 may include a boundary surface F-B at which a front-side surface F is bonded to a backside surface B.

In the image sensor EX4 described above, the third front-side bonding pad 415 included in the second middle layer 400-3 may be bonded to the fourth front-side bonding pad 507 included in the bottom layer 500. The second middle layer 400-3 and the bottom layer 500 may include a boundary surface F-F at which a front-side surface F is bonded to a front-side surface F.

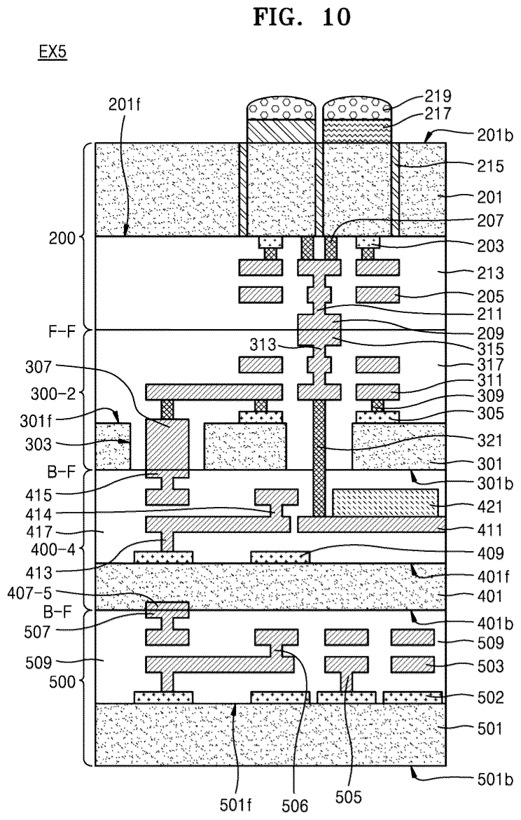

FIG. 10 is a schematic cross-sectional view of a structure of an image sensor EX5 according to an embodiment.

For example, the image sensor EX5 may be an example of the image sensor 100 of FIG. 1, according to embodiments. The image sensor EX5 may include the pixel PX of FIG. 1. In embodiments, the image sensor EX5 may be similar to the image sensor EX1 of FIG. 3 described above, except that the image sensor EX5 may include a first middle layer 300-2 and a second middle layer 400-4 as shown in FIG. 10. In the description below with reference to FIG. 10, description which is redundant or duplicative of the descriptions of FIG. 3 may be briefly given or omitted.

The image sensor EX5 may include four layers in which a bottom layer 500, the second middle layer 400-4, the first middle layer 300-2, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-2 may include a second substrate 301, a plurality of second transistors 305, a second backside bonding via 307, a second wiring layer 311, a second contact plug 309, a second front-side bonding pad 315, a second via plug 313, a second connection via plug 321, and a second insulation layer 317.

A first front-side bonding pad 209 included in the top layer 200 may be bonded to a second front-side bonding pad 315 included in the first middle layer 300-2. A first insulation layer 213 included in the top layer 200 may be bonded to a second insulation layer 317 included in the first middle layer 300-2. The top layer 200 and the first middle layer 300-2 may include a boundary surface F-F at which a front-side surface F is bonded to a front-side surface F.

The second substrate 301 may be a silicon substrate. The second substrate 301 may include a second front-side surface 301f and a second backside surface 301b corresponding to the second front-side surface 301f. The second transistor 305 may be formed on the second front-side surface 301f. A hole 303 passing through the second front-side surface 301f and the second backside surface 301b may be formed in the second substrate 301. The second backside bonding via 307 insulated by the second insulation layer 317 may be formed in the hole 303.

The second contact plug 309 and the second wiring layer 311 may be connected to the second transistor 305. The second contact plug 309 may include a metal layer (for example, a tungsten layer). The second contact plug 309 and the second wiring layer 311 may be connected to the second front-side bonding pad 315 and the second backside bonding via 307. The second backside bonding via 307, the second wiring layer 311, the second front-side bonding pad 315, and the second via plug 313 may include a metal layer (for example, a copper layer).

The second connection via plug 321 may be connected to the second wiring layer 311 to extend to the second middle layer 400-4 and may be connected to the third wiring layer 411. The second connection via plug 321 may be longer in length than the second via plug 313 in a vertical direction. The second connection via plug 321 may include a metal layer (for example, a tungsten layer).

The second middle layer 400-4 may include a third substrate 401, a plurality of third transistors 409, a third via 405, a third backside bonding pad 407, a third wiring layer 411, a third contact plug 413, a third front-side bonding pad 415, a third via plug 414, a third insulation layer 417, and a capacitor 421.

The second backside bonding via 307 included in the first middle layer 300-2 may be bonded to the third front-side bonding pad 415 included in the second middle layer 400-4. The second insulation layer 317 included in the first middle layer 300-2 and the second substrate 301 may be bonded to the third insulation layer 417 included in the second middle layer 400-4. The first middle layer 300-2 and the second middle layer 400-4 may include a boundary surface B-F at which a backside surface B is bonded to a front-side surface F.

The third substrate 401 may be a silicon substrate. The third substrate 401 may include a third front-side surface 401f and a third backside surface 401b corresponding to the third front-side surface 401f. The third transistor 409 may be formed on the third front-side surface 401f. The third backside bonding pad 407-5 may be disposed on the fourth backside surface 401b. The third contact plug 413 and the third wiring layer 411 may be connected to the third transistor 409. The capacitor 421 may be disposed on the third wiring layer 411. The third wiring layer 411 may be connected to the capacitor 421.

The third contact plug 413 may include a metal layer (for example, a tungsten layer). The third contact plug 413 and the third wiring layer 411 may be connected to the third front-side bonding pad 415. In some embodiments, the third backside bonding pad 407-5 may be electrically connected to the third wiring layer 411 of the third substrate 401. The third backside bonding via 407-5, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third backside bonding pad 407-5 included in the second middle layer 400-4 may be bonded to the fourth front-side bonding pad 507 included in the bottom layer 500. The third substrate 401 included in the second middle layer 400-4 may be bonded to the fourth insulation layer 509 included in the bottom layer 500. The second middle layer 400-4 and the bottom layer 500 may include a boundary surface B-F at which a backside surface B is bonded to a front-side surface F.

In the image sensor EX5 described above, the first front-side bonding pad 209 included in the top layer 200 may be bonded to the second front-side bonding pad 315 included in the first middle layer 300-2, and the top layer 200 and the first middle layer 300-2 may include a boundary surface F-F at which a front-side surface F is bonded to a front-side surface F.

In the image sensor EX5 described above, the second backside bonding via 307 included in the first middle layer 300-2 may be bonded to the third front-side bonding pad 415 included in the second middle layer 400-4. The first middle layer 300-2 and the second middle layer 400-4 may include a boundary surface B-F at which a backside surface B is bonded to a front-side surface F. The first middle layer 300-2 may be connected to the second middle layer 400-4 by the second connection via plug 321.

In the image sensor EX5 described above, the third backside bonding pad 407-5 included in the second middle layer 400-4 may be bonded to the fourth front-side bonding pad 507 included in the bottom layer 500. The second middle layer 400-4 and the bottom layer 500 may include a boundary surface B-F at which a backside surface B is bonded to a front-side surface F.

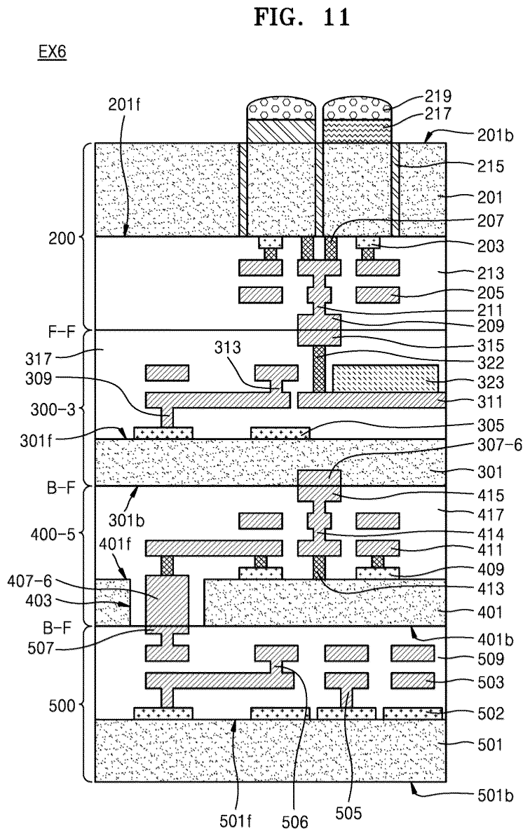

FIG. 11 is a schematic cross-sectional view of a structure of an image sensor according to an embodiment.

For example, the image sensor EX6 may be an example of the image sensor 100 of FIG. 1, according to embodiments. The image sensor EX6 may include the pixel PX of FIG. 1. In embodiments, the image sensor EX6 may be similar to the image sensor EX1 of FIG. 3 described above, except that the image sensor EX6 may include a first middle layer 300-3 and a second middle layer 400-5 as shown in FIG. 11. In the description below with reference to FIG. 11, description which is redundant or duplicative of the descriptions of FIG. 3 may be briefly given or omitted.

The image sensor EX6 may include four layers in which a bottom layer 500, the second middle layer 400-5, the first middle layer 300-3, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-3 may include a second substrate 301, a plurality of second transistors 305, a second backside bonding pad 307-6, a second wiring layer 311, a second contact plug 309, a second front-side bonding pad 315, a second via plug 313, a third connection via plug 322, and a second insulation layer 317.

A first front-side bonding pad 209 included in the top layer 200 may be bonded to a second front-side bonding pad 315 included in the first middle layer 300-3. A first insulation layer 213 included in the top layer 200 may be bonded to a second insulation layer 317 included in the first middle layer 300-3. The top layer 200 and the first middle layer 300-3 may include a boundary surface F-F at which a front-side surface F is bonded to a front-side surface F.

The second substrate 301 may be a silicon substrate. The second substrate 301 may include a second front-side surface 301f and a second backside surface 301b corresponding to the second front-side surface 301f. The second transistor 305 may be formed on the second front-side surface 301f. The second contact plug 309 and the second wiring layer 311 may be connected to the second transistor 305. The second contact plug 309 may include a metal layer (for example, a tungsten layer). The second contact plug 309 and the second wiring layer 311 may be connected to the second front-side bonding pad 315. The second wiring layer 311, the second front-side bonding pad 315, and the second via plug 313 may include a metal layer (for example, a copper layer).

The third connection via plug 322 may be connected to the second front-side bonding pad 315 and the second wiring layer 311. The third connection via plug 322 may be longer in length than the second via plug 313 in a vertical direction. The third connection via plug 322 may include a metal layer (for example, a tungsten layer). In some embodiments, the second backside bonding pad 307-6 may be electrically connected to the second wiring layer 311 of the second substrate 301.

The second middle layer 400-5 may include a third substrate 401, a plurality of third transistors 409, a third backside bonding via 407-6, a third wiring layer 411, a third contact plug 413, a third front-side bonding pad 415, a third via plug 414, and a third insulation layer 417.

The second backside bonding pad 307-6 included in the first middle layer 300-3 may be bonded to the third front-side bonding pad 415 included in the second middle layer 400-5. The second substrate 301 included in the first middle layer 300-3 may be bonded to the third insulation layer 417 included in the second middle layer 400-5. The first middle layer 300-3 and the second middle layer 400-5 may include a boundary surface B-F at which a backside surface B is bonded to a front-side surface F.

The third substrate 401 may be a silicon substrate. The third substrate 401 may include a third front-side surface 401f and a third backside surface 401b corresponding to the third front-side surface 401f. The third transistor 409 may be formed on the third front-side surface 401f.

A hole 403 passing through the third front-side surface 401f and the third backside surface 401b may be formed in the third substrate 401. The third backside bonding via 407-6 insulated by the third insulation layer 417 may be formed in the hole 403. The third backside bonding via 407-6 may be connected to the third via plug 414 and the third wiring layer 411.

The third contact plug 413 and the third wiring layer 411 may be connected to the third transistor 409. The third contact plug 413 may include a metal layer (for example, a tungsten layer). The third contact plug 413 and the third wiring layer 411 may be connected to the third front-side bonding pad 415. The third backside bonding via 407-6, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third backside bonding via 407-6 included in the second middle layer 400-5 may be bonded to the fourth front-side bonding pad 507 included in the bottom layer 500. The third substrate 401 included in the second middle layer 400-5 may be bonded to the fourth insulation layer 509 included in the bottom layer 500. The second middle layer 400-5 and the bottom layer 500 may include a boundary surface B-F at which a backside surface B is bonded to a front-side surface F.

In the image sensor EX6 described above, the first front-side bonding pad 209 included in the top layer 200 may be bonded to the second front-side bonding pad 315 included in the first middle layer 300-3, and the top layer 200 and the first middle layer 300-3 may include a boundary surface F-F at which a front-side surface F is bonded to a front-side surface F.

In the image sensor EX6 described above, the second backside bonding pad 307-6 included in the first middle layer 300-3 may be bonded to the third front-side bonding pad 415 included in the second middle layer 400-5. The first middle layer 300-3 and the second middle layer 400-5 may include a boundary surface B-F at which a backside surface B is bonded to a front-side surface F.

In the image sensor EX6 described above, the third backside bonding via 407-6 included in the second middle layer 400-5 may be bonded to the fourth front-side bonding pad 507 included in the bottom layer 500. The second middle layer 400-5 and the bottom layer 500 may include a boundary surface B-F at which a backside surface B is bonded to a front-side surface F.

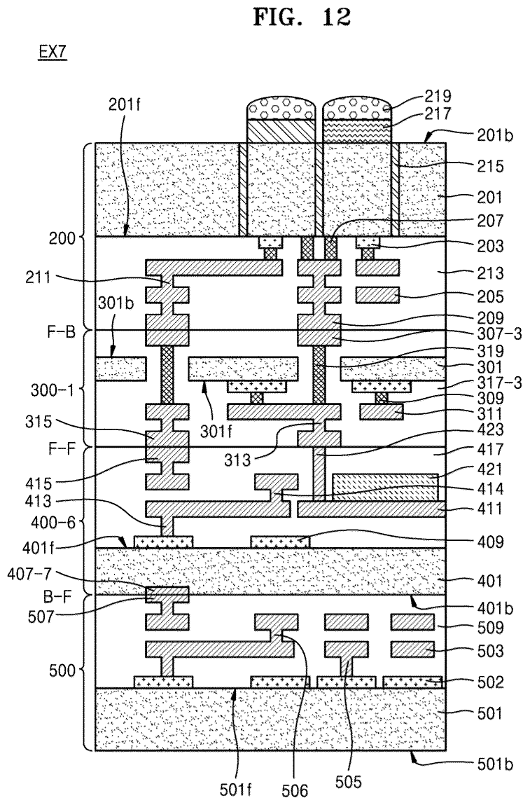

FIG. 12 is a schematic cross-sectional view of a structure of an image sensor EX7 according to an embodiment.

For example, the image sensor EX7 may be an example of the image sensor 100 of FIG. 1, according to embodiments. The image sensor EX7 may include the pixel PX of FIG. 1. In embodiments, the image sensor EX7 may be similar to the image sensor EX1 of FIG. 3 described above, except that the image sensor EX7 may include a first middle layer 300-1 and a second middle layer 400-6 as shown in FIG. 12. In the description below with reference to FIG. 12, description which is redundant or duplicative of the descriptions of FIG. 3 may be briefly given or omitted.

The image sensor EX7 may include four layers in which a bottom layer 500, the second middle layer 400-6, the first middle layer 300-1, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-1 may include a second substrate 301, a plurality of second transistors 305, a second backside bonding pad 307-3, a second wiring layer 311, a second contact plug 309, a second front-side bonding pad 315, a second via plug 313, a first connection via plug 319, a second front-side bonding pad 315, and a second insulation layer 317-3. The first middle layer 300-1 is described above with reference to FIG. 8, and thus, redundant or duplicative description thereof is omitted.

A first front-side bonding pad 209 included in the top layer 200 may be bonded to a second backside bonding pad 307-3 included in the first middle layer 300-1. A first insulation layer 213 included in the top layer 200 may be bonded to a second insulation layer 317-3 included in the first middle layer 300-1. The top layer 200 and the first middle layer 300-1 may include a boundary surface F-B at which a front-side surface F is bonded to a backside surface B.

The second middle layer 400-6 may include a third substrate 401, a plurality of third transistors 409, a third backside bonding pad 407-7, a third wiring layer 411, a third contact plug 413, a third front-side bonding pad 415, a third via plug 414, a third insulation layer 417, a capacitor 421, and a fourth connection via plug 423.

The second front-side bonding pad 315 included in the first middle layer 300-1 may be bonded to the third front-side bonding pad 415 included in the second middle layer 400-6. The second insulation layer 317-3 included in the first middle layer 300-1 may be bonded to the third insulation layer 417 included in the second middle layer 400-6. The first middle layer 300-1 and the second middle layer 400-6 may include a boundary surface F-F at which a front-side surface F is bonded to a front-side surface F.

The third substrate 401 may be a silicon substrate. The third substrate 401 may include a third front-side surface 401f and a third backside surface 401b corresponding to the third front-side surface 401f. The third transistor 409 may be formed on the third front-side surface 401f. The third contact plug 413 and the third wiring layer 411 may be connected to the third transistor 409.

The third contact plug 413 may include a metal layer (for example, a tungsten layer). The third contact plug 413 and the third wiring layer 411 may be connected to the third front-side bonding pad 415. The capacitor 421 may be disposed on the third wiring layer 411. The third wiring layer 411 may be connected to the capacitor 421. The third wiring layer 411, the third front-side bonding pad 415, and the third via plug 414 may include a metal layer (for example, a copper layer).

The fourth connection via plug 423 may be connected to the second front-side bonding pad 315 and the third wiring layer 411. The fourth connection via plug 423 may be longer in length than the third via plug 414 in a vertical direction. The fourth connection via plug 423 may include a metal layer (for example, a tungsten layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third backside bonding pad 407-7 included in the second middle layer 400-6 may be bonded to the fourth front-side bonding pad 507 included in the bottom layer 500. The third substrate 401 included in the second middle layer 400-6 may be bonded to the fourth insulation layer 509 included in the bottom layer 500. The second middle layer 400-6 and the bottom layer 500 may include a boundary surface B-F at which a backside surface B is bonded to a front-side surface F.

In the image sensor EX7 described above, the first front-side bonding pad 209 included in the top layer 200 may be bonded to the second backside bonding pad 307-3 included in the first middle layer 300-1, and the top layer 200 and the first middle layer 300-1 may include a boundary surface F-B at which a front-side surface F is bonded to a backside surface B.

In the image sensor EX7 described above, the second front-side bonding pad 315 included in the first middle layer 300-1 may be bonded to the third front-side bonding pad 415 included in the second middle layer 400-6. The first middle layer 300-1 and the second middle layer 400-6 may include a boundary surface F-F at which a front-side surface F is bonded to a front-side surface F.

In the image sensor EX7 described above, the third backside bonding pad 407-7 included in the second middle layer 400-6 may be bonded to the fourth front-side bonding pad 507 included in the bottom layer 500. The second middle layer 400-6 and the bottom layer 500 may include a boundary surface B-F at which a backside surface B is bonded to a front-side surface F.

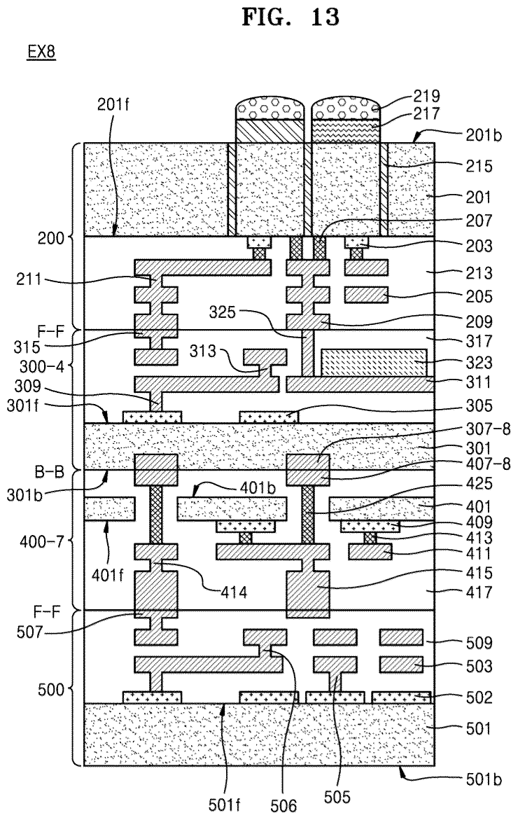

FIG. 13 is a schematic cross-sectional view of a structure of an image sensor EX8 according to an embodiment.

For example, the image sensor EX8 may be an example of the image sensor 100 of FIG. 1, according to embodiments. The image sensor EX8 may include the pixel PX of FIG. 1. In embodiments, the image sensor EX8 may be similar to the image sensor EX1 of FIG. 3 described above, except that the image sensor EX8 may include a first middle layer 300-4 and a second middle layer 400-7 as shown in FIG. 13. In the description below with reference to FIG. 13, description which is redundant or duplicative of the descriptions of FIG. 3 may be briefly given or omitted.

The image sensor EX8 may include four layers in which a bottom layer 500, a second middle layer 400-7, a first middle layer 300-4, and a top layer 200 are bonded to each other. The top layer 200 may include a first substrate 201, a plurality of first transistors 203, a first wiring layer 205, a first contact plug 207, a first front-side bonding pad 209, a first via plug 211, a first insulation layer 213, a pixel separation layer 215, a color filter 217, and a lens 219.

The first middle layer 300-4 may include a second substrate 301, a plurality of second transistors 305, a second backside bonding pad 307-8, a second wiring layer 311, a second contact plug 309, a second front-side bonding pad 315, a second via plug 313, a function device 323, a fifth connection via plug 325, and a second insulation layer 317.

A first front-side bonding pad 209 included in the top layer 200 may be bonded to the fifth connection via plug 325 included in the first middle layer 300-4. A first insulation layer 213 included in the top layer 200 may be bonded to a second insulation layer 317 included in the first middle layer 300-4. The top layer 200 and the first middle layer 300-4 may include a boundary surface F-F at which a front-side surface F is bonded to a front-side surface F.

The second substrate 301 may be a silicon substrate. The second substrate 301 may include a second front-side surface 301f and a second backside surface 301b corresponding to the second front-side surface 301f. The second transistor 305 may be formed on the second front-side surface 301f. The second contact plug 309 and the second wiring layer 311 may be connected to the second transistor 305.

The second contact plug 309 may include a metal layer (for example, a tungsten layer). The second contact plug 309 and the second wiring layer 311 may be connected to the second front-side bonding pad 315. The second wiring layer 311, the second front-side bonding pad 315, and the second via plug 313 may include a metal layer (for example, a copper layer). The function device 323 may be disposed on the second wiring layer 311. The function device 323 may be connected to the second wiring layer 311. In some embodiments, the function device 323 may include at least one of an image processing circuit, an ADC, and a capacitor. In some embodiments, the capacitor may include at least one of a MIM-type capacitor, a MOS capacitor, a trench capacitor, a PIP capacitor, and a 3D capacitor.

The fifth connection via plug 325 may be connected to the second front-side bonding pad 315 and the second wiring layer 311. The fifth connection via plug 325 may be longer in length than the second via plug 313 in a vertical direction. The fifth connection via plug 325 may include a metal layer (for example, a tungsten layer). Although not shown in FIG. 13 for convenience, the second backside bonding pad 307-8 may be electrically connected to the second wiring layer 311 of the second substrate 301.

The second middle layer 400-7 may include a third substrate 401, a plurality of third transistors 409, a third backside bonding pad 407-8, a third wiring layer 411, a third contact plug 413, a third front-side bonding pad 415, a third via plug 414, a third insulation layer 417, and a sixth connection via plug 425.

The second backside bonding pad 307-8 included in the first middle layer 300-4 may be bonded to the third backside bonding pad 407-8 included in the second middle layer 400-7. The second substrate 301 included in the first middle layer 300-4 may be bonded to the third insulation layer 417 included in the second middle layer 400-7. The first middle layer 300-4 and the second middle layer 400-7 may include a boundary surface B-B at which a backside surface B is bonded to a backside surface B.

The third substrate 401 may be a silicon substrate. The third substrate 401 may include a third front-side surface 401f and a third backside surface 401b corresponding to the third front-side surface 401f. The third transistor 409 may be formed on the third front-side surface 401f. The third contact plug 413 and the third wiring layer 411 may be connected to the third transistor 409. The capacitor 421 may be disposed on the third wiring layer 411. The third wiring layer 411 may be connected to the capacitor 421.

The third contact plug 413 may include a metal layer (for example, a tungsten layer). The third contact plug 413 and the third wiring layer 411 may be connected to the third front-side bonding pad 415. The third backside bonding pad 407-8, the third wiring layer 411, the third front-side bonding pad 415, and the third via plug 414 may include a metal layer (for example, a copper layer).

The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509.

The third front-side bonding pad 415 included in the second middle layer 400-7 may be bonded to the fourth front-side bonding pad 507 included in the bottom layer 500. The third insulation layer 417 included in the second middle layer 400-7 may be bonded to the fourth insulation layer 509 included in the bottom layer 500. The second middle layer 400-7 and the bottom layer 500 may include a boundary surface F-F at which a front-side surface F is bonded to a front-side surface F.

In the image sensor EX8 described above, the first front-side bonding pad 209 included in the top layer 200 may be bonded to fifth connection via plug 325 included in the first middle layer 300-4, and the top layer 200 and the first middle layer 300-3 may include a boundary surface F-F at which a front-side surface F is bonded to a front-side surface F.

In the image sensor EX8 described above, the second backside bonding pad 307-8 included in the first middle layer 300-4 may be bonded to the third backside bonding pad 407-8 included in the second middle layer 400-7. The first middle layer 300-4 and the second middle layer 400-7 may include a boundary surface B-B at which a backside surface B is bonded to a backside surface B.

In the image sensor EX8 described above, the third front-side bonding pad 415 included in the second middle layer 400-7 may be bonded to the fourth front-side bonding pad 507 included in the bottom layer 500. The second middle layer 400-7 and the bottom layer 500 may include a boundary surface F-F at which a front-side surface F is bonded to a front-side surface F.

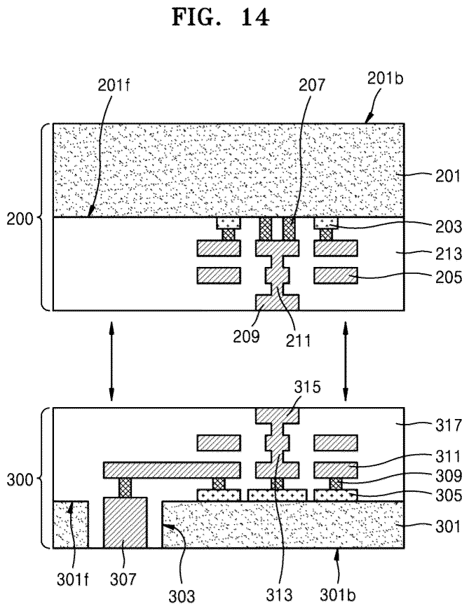

FIGS. 14 to 16 are cross-sectional views of a method of manufacturing the image sensor of FIG. 3, according to an embodiment.

In the description below with reference to FIGS. 14 to 16, description which is redundant or duplicative of the descriptions of FIG. 3 may be briefly given or omitted. Referring to FIG. 14, a top layer 200 may be prepared. The top layer 200 may include a first substrate 201, a plurality of first transistors 203, a first wiring layer 205, a first contact plug 207, a first front-side bonding pad 209, a first via plug 211, and a first insulation layer 213. The first substrate 201 may include a first front-side surface 201f and a first backside surface 201b corresponding to the first front-side surface 201f. In FIG. 14, for convenience, the pixel separation layer 215, the color filter 217, and the lens 219 each described above with reference to FIG. 3 are not illustrated.

A first middle layer 300 may be prepared. The first middle layer 300 may include a second substrate 301, a plurality of second transistors 305, a second backside bonding via 307, a second wiring layer 311, a second contact plug 309, a second front-side bonding pad 315, a second via plug 313, and a second insulation layer 317.

The second substrate 301 may include a second front-side surface 301f and a second backside surface 301b corresponding to the second front-side surface 301f. A hole 303 passing through the second front-side surface 301f and the second backside surface 301b may be formed in the second substrate 301. The second backside bonding through via 307 insulated by the second insulation layer 317 may be formed in the hole 303.

A first front-side bonding pad 209 included in the top layer 200 may be bonded to a second front-side bonding pad 315 included in the first middle layer 300 in a vertical direction. A first insulation layer 213 included in the top layer 200 may be bonded to a second insulation layer 317 included in the first middle layer 300 in the vertical direction. In a case in which each of the first front-side bonding pad 209 and the second front-side bonding pad 315 includes a copper layer, a copper pad may be bonded to a copper pad.

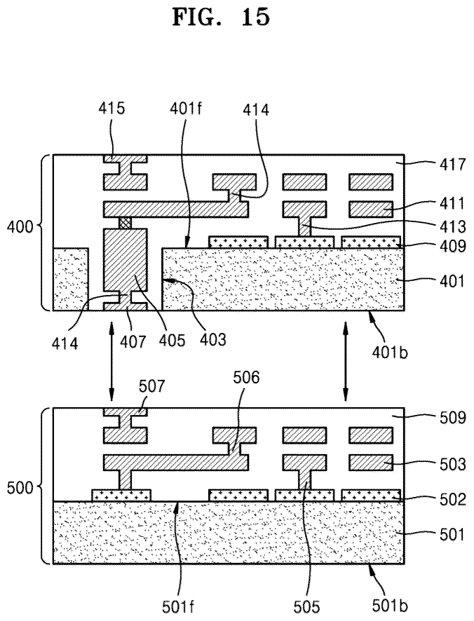

Referring to FIG. 15, a second middle layer 400 may be prepared. The second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

The third substrate 401 may include a third front-side surface 401f and a third backside surface 401b corresponding to the third front-side surface 401f. A hole 403 passing through the third front-side surface 401f and the third backside surface 401b may be formed in the third substrate 401. The third via 405 insulated by the third insulation layer 417 may be formed in the hole 403. The third via 405 may be connected to the third backside bonding pad 407 through the third via plug 414.

A bottom layer 500 may be prepared. The bottom layer 500 may include a fourth substrate 501, a plurality of fourth transistors 502, a fourth wiring layer 503, a fourth contact plug 505, a fourth front-side bonding pad 507, a fourth via plug 506, and a fourth and a fourth backside surface 501b corresponding to the fourth front-side surface 501f.

The third backside bonding pad 407 included in the second middle layer 400 may be bonded to the fourth front-side bonding pad 507 included in the bottom layer 500 in the vertical direction. The third insulation layer 417 included in the second middle layer 400 and the third substrate 401 may be bonded to the fourth insulation layer 509 included in the bottom layer 500 in an the vertical direction. In a case in which each of the third backside bonding pad 407 and the fourth front-side bonding pad 507 includes a copper layer, a copper pad may be bonded to a copper pad.

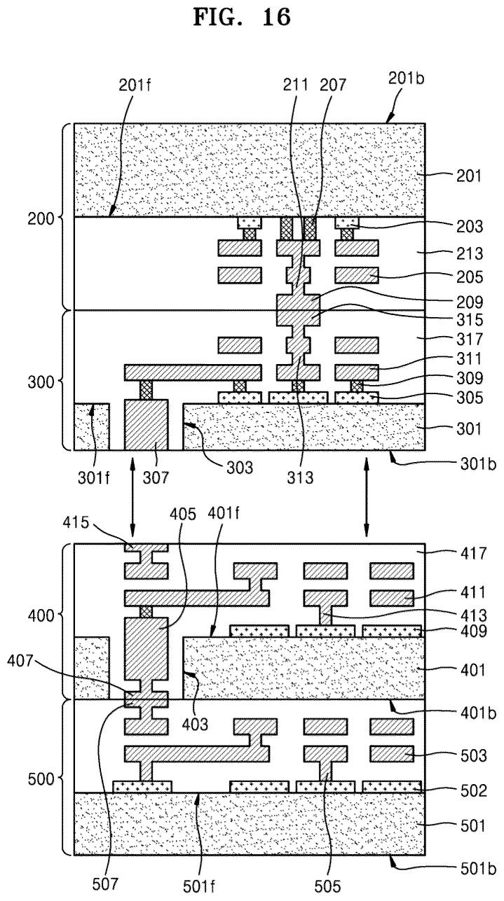

Referring to FIG. 16, the top layer 200 and the first middle layer 300 bonded to each other as described above with reference to FIG. 14 may be prepared. The second middle layer 400 and the bottom layer 500 bonded to each other as described above with reference to FIG. 15 may be prepared. The second backside bonding via 307 included in the first middle layer 300 may be bonded to the third front-side bonding pad 415 included in the second middle layer 400 in the vertical direction.

The second insulation layer 317 included in the first middle layer 300 and the second substrate 301 may be bonded to the third insulation layer 417 included in the second middle layer 400 in the vertical direction. In a case in which each of the second backside bonding via 307 and the third front-side bonding pad 415 includes a copper layer, a copper via may be bonded to a copper pad. Based on such a process, the image sensor EX1 of FIG. 3 may be manufactured.

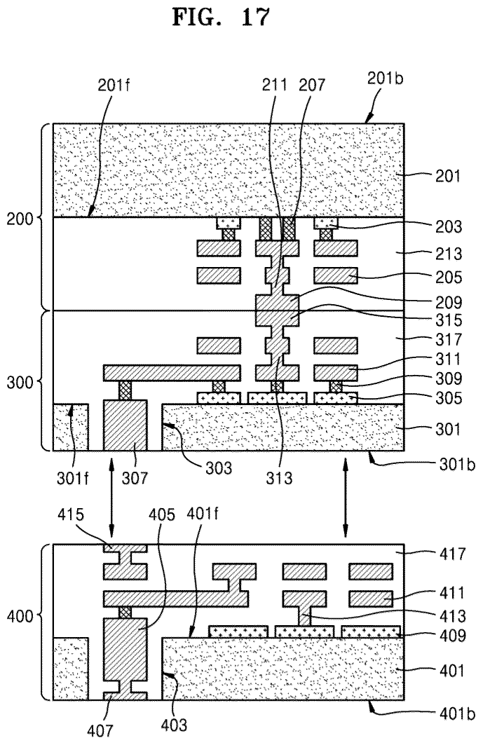

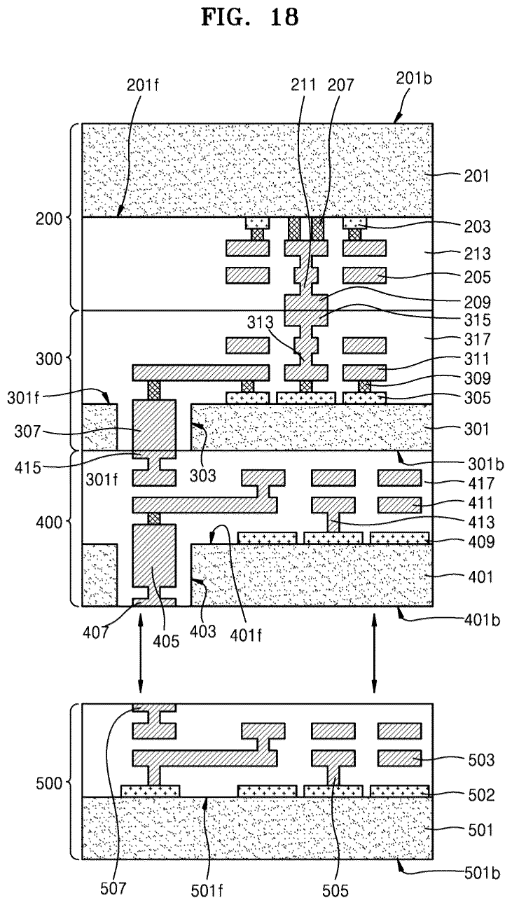

FIGS. 17 and 18 are cross-sectional views of a method of manufacturing the image sensor of FIG. 3, according to an embodiment.

In the description below with reference to FIGS. 17 and 18, description which is redundant or duplicative of the descriptions of FIGS. 3 and 14 to 16 may be briefly given or omitted. Referring to FIG. 17, the top layer 200 and the first middle layer 300 bonded to each other as described above with reference to FIG. 14 may be prepared. The top layer 200 may be bonded onto the first middle layer 300. The first middle layer 300, as described above, may include a second substrate 301, a plurality of second transistors 305, a second backside bonding via 307, a second wiring layer 311, a second contact plug 309, a second front-side bonding pad 315, a second via plug 313, and a second insulation layer 317.

As described above with reference to FIG. 15, the second middle layer 400 may be prepared. The second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

The second backside bonding via 307 included in the first middle layer 300 may be bonded to the third front-side bonding pad 415 included in the second middle layer 400 in the vertical direction. The second substrate 301 and the second insulation layer 317 included in the first middle layer 300 may be bonded to the third insulation layer 417 included in the second middle layer 400 in the vertical direction. In a case in which each of the second backside bonding via 307 and the third front-side bonding pad 415 includes a copper layer, a copper via may be bonded to a copper pad.

Referring to FIG. 18, the top layer 200, the first middle layer 300, and the second middle layer 400 bonded to each other as described above with reference to FIG. 17 may be prepared. The first middle layer 300 and the top layer 200 may be bonded onto the second middle layer 400. As described above, the second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

The bottom layer 500 may be prepared. The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509. The fourth substrate 501 may include a fourth front-side surface 501f and a fourth backside surface 501b corresponding to the fourth front-side surface 501f.

The third backside bonding pad 407 included in the second middle layer 400 may be bonded to the fourth front-side bonding pad 507 included in the bottom layer 500 in the vertical direction. The third insulation layer 417 included in the second middle layer 400 and the third substrate 401 may be bonded to the fourth insulation layer 509 included in the bottom layer 500 in the vertical direction. In a case in which each of the third backside bonding pad 407 and the fourth front-side bonding pad 507 includes a copper layer, a copper pad may be bonded to a copper pad. Based on such a process, the image sensor EX1 of FIG. 3 may be manufactured.

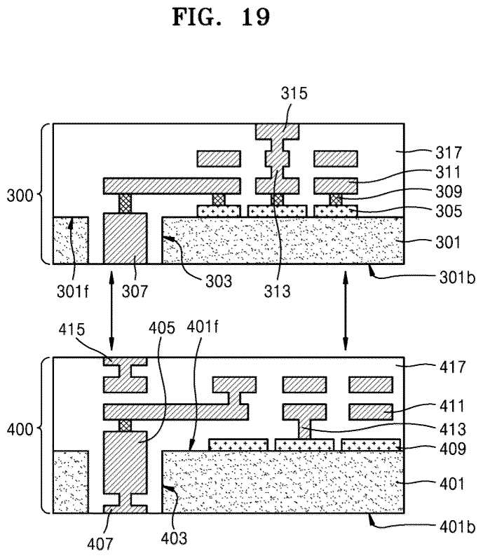

FIGS. 19 to 21 are cross-sectional views of a method of manufacturing the image sensor of FIG. 3, according to an embodiment.

In the description below with reference to FIGS. 19 to 21, description which is redundant or duplicative of the descriptions of FIGS. 3 and 14 to 18 may be briefly given or omitted. Referring to FIG. 19, a first middle layer 300 may be prepared. The first middle layer 300 may include a second substrate 301, a plurality of second transistors 305, a second backside bonding via 307, a second wiring layer 311, a second contact plug 309, a second front-side bonding pad 315, a second via plug 313, and a second insulation layer 317.

The second substrate 301 may include a second front-side surface 301f and a second backside surface 301b corresponding to the second front-side surface 301f. A hole 303 passing through the second front-side surface 301f and the second backside surface 301b may be formed in the second substrate 301. The second backside bonding via 307 insulated by the second insulation layer 317 may be formed in the hole 303.

A second middle layer 400 may be prepared. The second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

The third substrate 401 may include a third front-side surface 401f and a third backside surface 401b corresponding to the third front-side surface 401f. A hole 403 passing through the third front-side surface 401f and the third backside surface 401b may be formed in the third substrate 401. The third via 405 insulated by the third insulation layer 417 may be formed in the hole 403. The third via 405 may be connected to the third backside bonding pad 407 through the third via plug 414.

The second backside bonding via 307 included in the first middle layer 300 may be bonded to the third front-side bonding pad 415 included in the second middle layer 400 in the vertical direction. The second insulation layer 317 included in the first middle layer 300 may be bonded to the third insulation layer 417 included in the second middle layer 400 in the vertical direction. In a case in which each of the second backside bonding via 307 and the third front-side bonding pad 415 includes a copper layer, a copper via may be bonded to a copper pad.

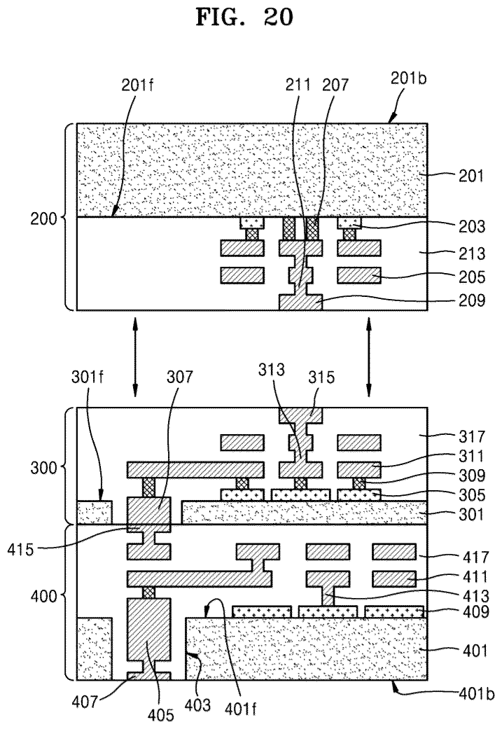

Referring to FIG. 20, a top layer 200 may be prepared. The top layer 200 may include a first substrate 201, a plurality of first transistors 203, a first wiring layer 205, a first contact plug 207, a first front-side bonding pad 209, a first via plug 211, and a first insulation layer 213. The first substrate 201 may include a first front-side surface 201f and a first backside surface 201b corresponding to the first front-side surface 201f. In FIG. 20, for convenience, the pixel separation layer 215, the color filter 217, and the lens 219 each described above with reference to FIG. 3 are not illustrated.

The first middle layer 300 and the second middle layer 400 bonded to each other as described above with reference to FIG. 19 may be prepared. The first middle layer 300 may be bonded onto the second middle layer 400. The top layer 200 may be bonded onto the bonded first middle layer 300 in the vertical direction.

A first front-side bonding pad 209 included in the top layer 200 may be bonded to a second front-side bonding pad 315 included in the first middle layer 300 in the vertical direction. A first insulation layer 213 included in the top layer 200 may be bonded to a second insulation layer 317 included in the first middle layer 300 in the vertical direction. In a case in which each of the first front-side bonding pad 209 and the second front-side bonding pad 315 includes a copper layer, a copper pad may be bonded to a copper pad.

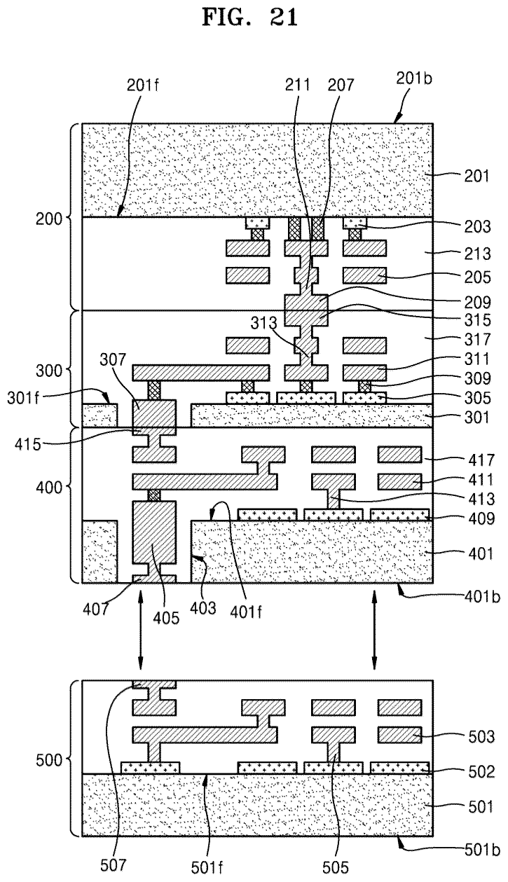

Referring to FIG. 21, the top layer 200, the first middle layer 300, and the second middle layer 400 bonded to each other as described above with reference to FIG. 20 may be prepared. The first middle layer 300 and the top layer 200 may be bonded onto the second middle layer 400. As described above, the second middle layer 400 may include a third substrate 401, a plurality of third transistors 409, a third via 405, a third backside bonding pad 407, a third wiring layer 411, a third contact plug 413, a third front-side bonding pad 415, a third via plug 414, and a third insulation layer 417.

A bottom layer 500 may be prepared. The bottom layer 500 may include a fourth substrate 501, a plurality of fourth transistors 502, a fourth wiring layer 503, a fourth contact plug 505, a fourth front-side bonding pad 507, a fourth via plug 506, and a fourth and a fourth backside surface 501b corresponding to the fourth front-side surface 501f.

The third backside bonding pad 407 included in the second middle layer 400 may be bonded to the fourth front-side bonding pad 507 included in the bottom layer 500 in the vertical direction. The third insulation layer 417 included in the second middle layer 400 and the third substrate 401 may be bonded to the fourth insulation layer 509 included in the bottom layer 500 in the vertical direction. In a case in which each of the third backside bonding pad 407 and the fourth front-side bonding pad 507 includes a copper layer, a copper pad may be bonded to a copper pad. Based on such a process, the image sensor EX1 of FIG. 3 may be manufactured.

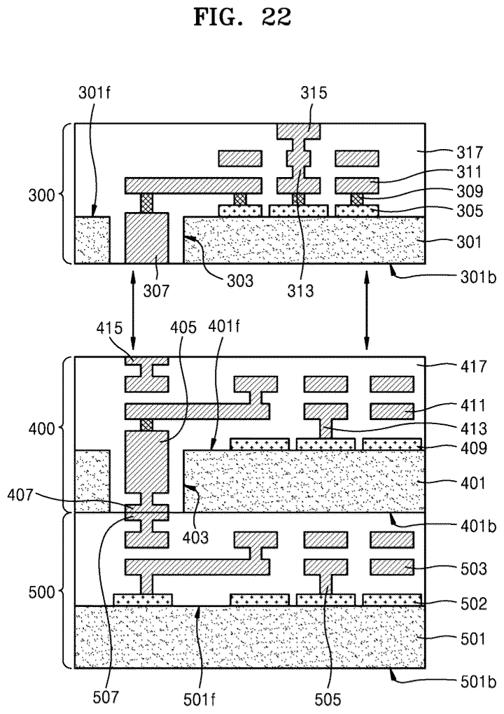

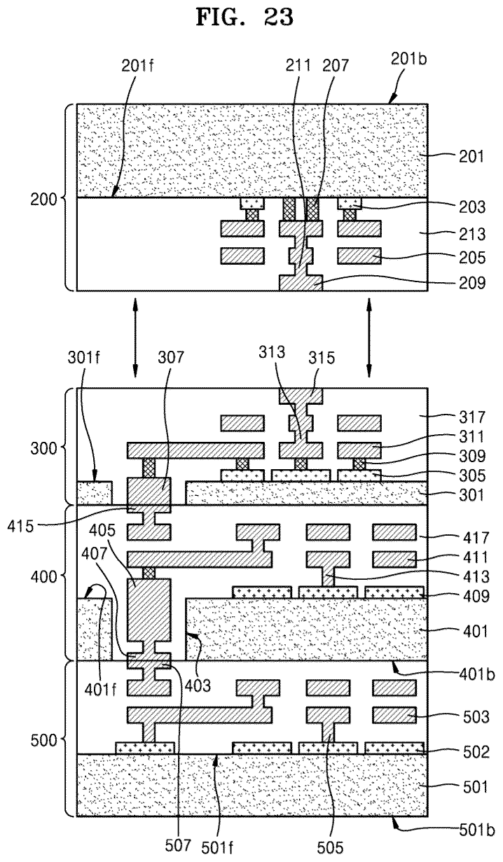

FIGS. 22 and 23 are cross-sectional views of a method of manufacturing the image sensor of FIG. 3, according to an embodiment. In the description below with reference to FIGS. 22 and 23, description which is redundant or duplicative of the descriptions of FIGS. 3 and 14 to 21 may be briefly given or omitted.

Referring to FIG. 22, a first middle layer 300 may be prepared. The first middle layer 300 may include a second substrate 301, a plurality of second transistors 305, a second backside bonding via 307, a second wiring layer 311, a second contact plug 309, a second front-side bonding pad 315, a second via plug 313, and a second insulation layer 317.

The second substrate 301 may include a second front-side surface 301f and a second backside surface 301b corresponding to the second front-side surface 301f. A hole 303 passing through the second front-side surface 301f and the second backside surface 301b may be formed in the second substrate 301. The second backside bonding via 307 insulated by the second insulation layer 317 may be formed in the hole 303.

The second middle layer 400 and the bottom layer 500 bonded to each other as described above may be prepared. The third backside bonding pad 407 included in the second middle layer 400 may be bonded to the fourth front-side bonding pad 507 included in the bottom layer 500. The third substrate 401 and the third insulation layer 417 included in the second middle layer 400 may be bonded to the fourth insulation layer 509 included in the bottom layer 500.

The second backside bonding via 307 included in the first middle layer 300 may be bonded to the third front-side bonding pad 415 included in the second middle layer 400 in the vertical direction. The second insulation layer 317 included in the first middle layer 300 may be bonded to the third insulation layer 417 included in the second middle layer 400 in the vertical direction. In a case in which each of the second backside bonding via 307 and the third front-side bonding pad 415 includes a copper layer, a copper via may be bonded to a copper pad.

Referring to FIG. 23, a top layer 200 may be prepared. The top layer 200 may include a first substrate 201, a plurality of first transistors 203, a first wiring layer 205, a first contact plug 207, a first front-side bonding pad 209, a first via plug 211, and a first insulation layer 213. The first substrate 201 may include a first front-side surface 201f and a first backside surface 201b corresponding to the first front-side surface 201f. In FIG. 23, for convenience, the pixel separation layer 215, the color filter 217, and the lens 219 each described above with reference to FIG. 3 are not illustrated.

The first middle layer 300, the second middle layer 400, and the bottom layer 500 bonded to each other as described above with reference to FIG. 22 may be prepared. A first front-side bonding pad 209 included in the top layer 200 may be bonded to a second front-side bonding pad 315 included in the first middle layer 300 in the vertical direction. A first insulation layer 213 included in the top layer 200 may be bonded to a second insulation layer 317 included in the first middle layer 300 in the vertical direction. In a case in which each of the first front-side bonding pad 209 and the second front-side bonding pad 315 includes a copper layer, a copper pad may be bonded to a copper pad. Based on such a process, the image sensor EX1 of FIG. 3 may be manufactured.

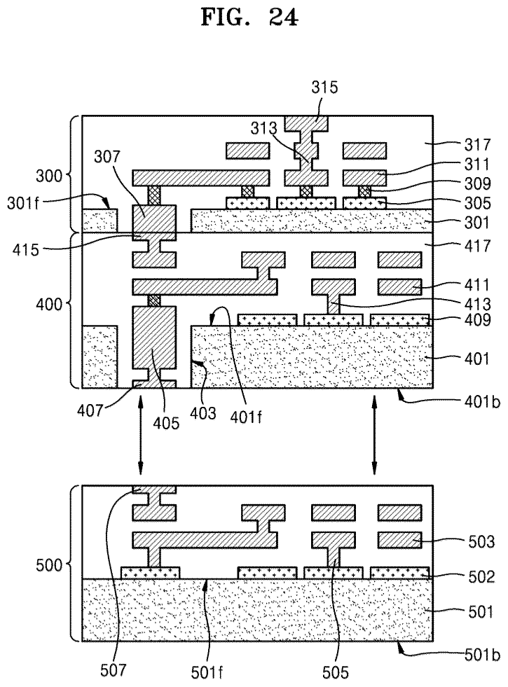

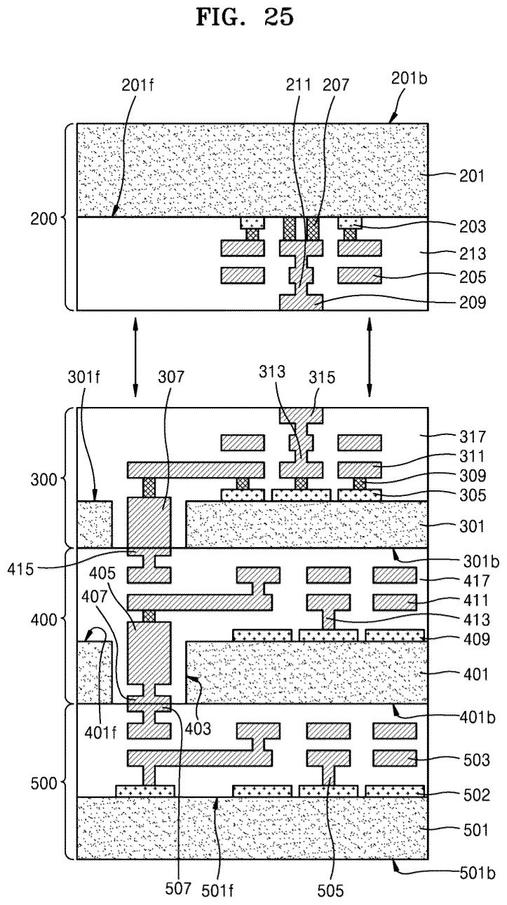

FIGS. 24 and 25 are cross-sectional views of a method of manufacturing the image sensor of FIG. 3, according to an embodiment. In the description below with reference to FIGS. 24 and 25, description which is redundant or duplicative of the descriptions of FIGS. 3 and 14 to 23 may be briefly given or omitted.

Referring to FIG. 24, the first middle layer 300 and the second middle layer 400 bonded to each other as described above with reference to FIG. 19 may be prepared. The second backside bonding via 307 included in the first middle layer 300 may be bonded to the third front-side bonding pad 415 included in the second middle layer 400. The second insulation layer 317 included in the first middle layer 300 may be bonded to the third insulation layer 417 included in the second middle layer 400.

A bottom layer 500 may be prepared. The bottom layer 500 may include a fourth substrate 501, a plurality of fourth transistors 502, a fourth wiring layer 503, a fourth contact plug 505, a fourth front-side bonding pad 507, a fourth via plug 506, and a fourth insulation layer 509. The fourth substrate 501 may include a fourth front-side surface 501f and a fourth backside surface 501b corresponding to the fourth front-side surface 501f.

The third backside bonding pad 407 included in the second middle layer 400 may be bonded to the fourth front-side bonding pad 507 included in the bottom layer 500 in the vertical direction. The third insulation layer 417 included in the second middle layer 400 and the third substrate 401 may be bonded to the fourth insulation layer 509 included in the bottom layer 500 in the vertical direction.

Referring to FIG. 25, a top layer 200 may be prepared. The top layer 200 may include a first substrate 201, a plurality of first transistors 203, a first wiring layer 205, a first contact plug 207, a first front-side bonding pad 209, a first via plug 211, and a first insulation layer 213. The first substrate 201 may include a first front-side surface 201f and a first backside surface 201b corresponding to the first front-side surface 201f. In FIG. 25, for convenience, the pixel separation layer 215, the color filter 217, and the lens 219 each described above with reference to FIG. 3 are not illustrated.

The first middle layer 300, the second middle layer 400, and the bottom layer 500 bonded to each other as described above with reference to FIG. 23 may be prepared. A first front-side bonding pad 209 included in the top layer 200 may be bonded to a second front-side bonding pad 315 included in the first middle layer 300 in the vertical direction. A first insulation layer 213 included in the top layer 200 may be bonded to a second insulation layer 317 included in the first middle layer 300 in the vertical direction. In a case in which each of the first front-side bonding pad 209 and the second front-side bonding pad 315 includes a copper layer, a copper pad may be bonded to a copper pad. Based on such a process, the image sensor EX1 of FIG. 3 may be manufactured.

The description of embodiments above and in the drawings is not intended to limit a meaning or the scope of the disclosure as defined in the following claims. Therefore, it may be understood by those of ordinary skill in the art that the scope of the disclosure may include various modifications and other equivalent embodiments. Accordingly, the spirit and scope of the disclosure may be defined based on the spirit and scope of the following claims.

While the embodiments are particularly shown and described herein, it will be understood that various changes in form and details may be made therein without departing from the spirit and scope of the following claims.

1. An image sensor comprising:
a top layer comprising a photodiode included in a pixel and a transfer transistor configured to transfer an electrical signal generated by the photodiode;
a first middle layer under the top layer and bonded to the top layer, wherein the first middle layer comprises at least one capacitor connected to the transfer transistor through a first output node connected to the transfer transistor, and at least one sampling transistor connected to the at least one capacitor and configured to control the at least one capacitor;
a second middle layer under the first middle layer and bonded to the first middle layer, wherein the second middle layer comprises a source-follow transistor connected to the at least one sampling transistor through a second output node; and
a bottom layer under the second middle layer and bonded to the second middle layer, wherein the bottom layer comprises an analog-to-digital converter (ADC) circuit configured to process a pixel signal output through the source-follow transistor.

2. The image sensor of claim 1, wherein the first middle layer further comprises a floating diffusion node connected to the transfer transistor, a conversion gain transistor connected to the floating diffusion node, and a reset transistor connected to the conversion gain transistor.

3. The image sensor of claim 1, wherein the first middle layer further comprises a floating diffusion node connected to the transfer transistor, a second source-follow transistor connected to the floating diffusion node, a precharge selection transistor connected to the second source-follow transistor, and a precharge transistor connected to the second source-follow transistor, and
wherein at least one of the first middle layer and the second middle layer further comprises a selection transistor connected to the source-follow transistor.

4. The image sensor of claim 1, wherein the top layer further comprises a first front-side bonding pad,
wherein the first middle layer further comprises a second front-side bonding pad and a second backside bonding pad, and the first front-side bonding pad is bonded to the second front-side bonding pad or the second backside bonding pad.

5. (canceled)

6. The image sensor of claim 1, wherein the first middle layer further comprises a second backside bonding via or a second backside bonding pad,
wherein the second middle layer further comprises a third front-side bonding pad or a third backside bonding via, and
wherein the second backside bonding via or the second backside bonding pad is bonded to the third front-side bonding pad or the third backside bonding via.

7. (canceled)

8. The image sensor of claim 1, wherein the first middle layer further comprises a second front-side bonding pad,
wherein the second middle layer further comprises a third front-side bonding pad or a third backside bonding via, and
wherein the second front-side bonding pad of the first middle layer is bonded to the third front-side bonding pad or the third backside bonding via.

9-10. (canceled)

11. The image sensor of claim 1, wherein the second middle layer further comprises a third backside bonding pad, a third backside bonding via, or a third front-side bonding pad,
wherein the bottom layer further comprises a fourth front-side bonding pad, and
wherein the third backside bonding pad, the third backside bonding via, or the third front-side bonding pad is bonded to the fourth front-side bonding pad.

12. An image sensor comprising:
a top layer comprising a photodiode included in a pixel and a transfer transistor configured to transfer an electrical signal generated by the photodiode;
a first middle layer under the top layer and bonded to the top layer, wherein the first middle layer comprises a source-follow transistor connected to the transfer transistor through a floating diffusion node;
a second middle layer under the first middle layer and bonded to the first middle layer, wherein the second middle layer comprises at least one capacitor connected to the transfer transistor through the floating diffusion node and at least one switching transistor connected to the at least one capacitor and configured to control the at least one capacitor; and
a bottom layer under the second middle layer and bonded to the second middle layer, wherein the bottom layer comprises an analog-to-digital converter (ADC) circuit configured to process a pixel signal output through the source-follow transistor.

13. The image sensor of claim 12, wherein the at least one switching transistor comprise a first switching transistor connected to the floating diffusion node and a second switching transistor connected to the floating diffusion node.

14. (canceled)

15. The image sensor of claim 12, wherein the top layer further comprises a first front-side bonding pad,
wherein the first middle layer further comprises a second front-side bonding pad and a second backside bonding pad, and
wherein the first front-side bonding pad of the top layer is bonded to the second front-side bonding pad or the second backside bonding pad.

16. The image sensor of claim 12, wherein the first middle layer further comprises a second backside bonding via or a second backside bonding pad,
wherein the second middle layer further comprises a third front-side bonding pad or a third backside bonding via, and
wherein the second backside bonding via or the second backside bonding pad of the first middle layer is bonded to the third front-side bonding pad or the third backside bonding via.

17. The image sensor of claim 12, wherein the second middle layer further comprises a third backside bonding pad, a third backside bonding via, or a third front-side bonding pad,
wherein the bottom layer further comprises a fourth front-side bonding pad, and
wherein the third backside bonding pad, the third backside bonding via, or the third front-side bonding pad of the second middle layer is bonded to the fourth front-side bonding pad.

18-20. (canceled)

21. An image sensor comprising:
a top layer comprising a photodiode included in a pixel and a transfer transistor configured to transfer an electrical signal generated by the photodiode;
a first middle layer under the top layer and bonded to the top layer, wherein the first middle layer comprises a source-follow transistor connected to the transfer transistor through a first output node;
a second middle layer under the first middle layer and bonded to the first middle layer, wherein the second middle layer comprises at least one capacitor connected to the source-follow transistor, and at least one sampling transistor connected to the at least one capacitor and configured to control the at least one capacitor; and
a bottom layer under the second middle layer and bonded to the second middle layer, wherein the bottom layer comprises an analog-to-digital converter (ADC) circuit configured to process a pixel signal output through the source-follow transistor.

22. The image sensor of claim 21, wherein the first middle layer further comprises a floating diffusion node connected to the transfer transistor, a conversion gain transistor connected to the floating diffusion node, and a reset transistor connected to the conversion gain transistor.

23. The image sensor of claim 21, wherein the first middle layer further comprises a floating diffusion node connected to the transfer transistor, a second source-follow transistor connected to the floating diffusion node, a precharge selection transistor connected to the second source-follow transistor, and a precharge transistor connected to the second source-follow transistor.

24. The image sensor of claim 21, wherein the bottom layer further comprises a selection transistor connected to the source-follow transistor.

25. The image sensor of claim 21, wherein the top layer further comprises a first front-side bonding pad,
wherein the first middle layer further comprises a second front-side bonding pad and a second backside bonding pad, and the first front-side bonding pad is bonded to the second front-side bonding pad or the second backside bonding pad of the first middle layer.

26. The image sensor of claim 21, wherein the first middle layer further comprises a second backside bonding via or a second backside bonding pad,
wherein the second middle layer further comprises a third front-side bonding pad or a third backside bonding via, and
wherein the second backside bonding via or the second backside bonding pad is bonded to the third front-side bonding pad or the third backside bonding via.

27. The image sensor of claim 21, wherein the first middle layer further comprises a second front-side bonding pad,
wherein the second middle layer further comprises a third front-side bonding pad or a third backside bonding via, and
wherein the second front-side bonding pad of the first middle layer is bonded to the third front-side bonding pad or the third backside bonding via.

28. The image sensor of claim 21, wherein the second middle layer further comprises a third backside bonding pad, a third backside bonding via, or a third front-side bonding pad,
wherein the bottom layer further comprises a fourth front-side bonding pad, and
wherein the third backside bonding pad, the third backside bonding via, or the third front-side bonding pad is bonded to the fourth front-side bonding pad.

29-31. (canceled)
